(19) United States
(12) Patent Application Publication
(10) Pub. No.: US 2025/0372135 A1
(43) Pub. Date: Dec. 4, 2025

(54) MEMORY DEVICE AND METHOD OF OPERATING THE SAME

(71) Applicant: TAIWAN SEMICONDUCTOR MANUFACTURING COMPANY, LTD., Hsinchu (TW)

(72) Inventor: Hyunsung HONG, Hsinchu (TW)

(21) Appl. No.: 18/676,826

(22) Filed: May 29, 2024

(51) Int. Cl. G11C 8/18; G11C 7/08; G11C 7/10; G11C 8/08

(52) U.S. Cl. CPC G11C 8/18; G11C 7/08; G11C 7/1069; G11C 8/08

(57) ABSTRACT

A memory device includes a memory cell array including a first memory cell coupled to a first word line and a second memory cell coupled to a second word line; and a word line driver coupled to the memory cell array and configured to drive the first and second word lines with a word line signal having a pulse. A leading edge of the word line signal pulse is delayed for the word line signal applied to the first word line relative to the word line signal applied to the second word line.

### BACKGROUND

The semiconductor integrated circuit (IC) industry has produced a wide variety of digital devices to address issues in a number of different areas. Some of these digital devices, such as memory devices, are configured for the storage of data. A memory device includes a memory cell coupled to a word line. A read operation to read data stored in the memory cell includes driving the word line with a word line signal. As ICs have become smaller and more complex, the resistance of conductive lines within these digital devices have also changed, affecting line voltages and overall IC performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic diagram of a memory device according to an embodiment, and

FIG. 1B is a schematic diagram of a memory cell array and a sense amplifier array of FIG. 1A according to an embodiment.

FIG. 2 is a graph of word line and bit line signals associated with the development of a differential bit line voltage and a related read margin.

FIG. 3 is a graph of read margins in activated word lines that use varied word line pulse widths according to an embodiment.

FIGS. 4A and 4B are sequential block diagrams and corresponding signals using varied internal clock signals to vary word line pulse widths according to an embodiment.

FIG. 5A is a schematic diagram of a clock generator of FIG. 1A according to an embodiment.

FIG. 5B is a schematic diagram of a sense amplifier array of FIG. 1A according to an embodiment.

FIG. 6 is a flow chart of a method of a read operation on a memory cell according to an embodiment.

FIG. 7 is a block diagram of a word line addressing scheme according to an embodiment.

FIG. 8 is a block diagram of a memory device according to an embodiment.

FIG. 9 is a graph of signals employed in driving a word line in a memory according to an embodiment.

FIGS. 10A and 10B are block diagrams of a correspondence between row address-derived signals and internal clock signals according to an embodiment.

FIG. 11 is a schematic diagram of a circuit for generating a variable internal clock signal pulse width according to an embodiment.

FIGS. 12 and 13 are schematic diagrams of circuits for generating a variable internal clock signal pulse width of FIG. 8 according to embodiments, and FIG. 14 is a graph of signals employed in driving a word line in a memory device using the circuits of FIGS. 12 and 13 according to an embodiment.

FIGS. 15 and 16 are schematic diagrams of circuits for generating a variable internal clock signal pulse width of FIG. 8 according to embodiments, and FIG. 17 is a graph of signals employed in driving a word line in a memory device using the circuits of FIGS. 15 and 16 according to an embodiment.

FIG. 18 is a block diagram of a memory device according to an embodiment.

FIGS. 19 and 20 are schematic diagrams of circuits for generating a variable internal clock signal pulse width of FIG. 18 according to embodiments, and FIG. 21 is a graph of signals employed in driving a word line in a memory device using the circuits of FIGS. 19 and 20 according to an embodiment.

FIGS. 22 and 23 are schematic diagrams of circuits for generating a variable internal clock signal pulse width of FIG. 18 according to embodiments, and FIG. 24 is a graph of signals employed in driving a word line in a memory device using the circuits of FIGS. 22 and 23 according to an embodiment.

FIG. 25 is a block diagram of a memory device according to an embodiment.

FIGS. 26 and 27 are schematic diagrams of circuits for generating a variable internal clock signal pulse width of FIG. 25 according to embodiments, and FIG. 28 is a graph of signals employed in driving a word line in a memory device using the circuits of FIGS. 26 and 27 according to an embodiment.

FIGS. 29 and 30 are schematic diagrams of circuits for generating a variable internal clock signal pulse width of FIG. 25 according to embodiments, and FIG. 31 is a graph of signals employed in driving a word line in a memory device using the circuits of FIGS. 29 and 30 according to an embodiment.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, merely examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” or the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In a memory device that includes a memory cell array and a word line driver, the word line driver is configured to drive a word line connected to a memory cell of the memory cell array with a word line signal having a pulse of a predetermined width (pulse width) during a read operation on the memory cell. To read from the memory cell, the pulse width of the word line signal controls a time for a bit line signal to develop sufficient read margin. To read from the memory cell having a complementary bit line pair, a differential voltage of at least the read margin is developed, based on the pulse width of the word line signal.

The voltage (or differential voltage) developed on the bit lines develops over a period of time that is proportional to the pulse width of the word line signal, with a longer pulse width corresponding to a greater voltage being developed. Also, the rate of voltage (or differential voltage) development on the bit lines is proportional to length of the bit lines (which corresponds to a distance between a sense amplifier and the memory cell) due to length-dependent resistance and capacitance (RC) characteristics of the bit lines, with longer bit lines corresponding to a slower (i.e., lower rate of) development of the voltage (or differential voltage). The pulse width of the word line signal is controlled in consideration of the RC characteristics of the bit lines.

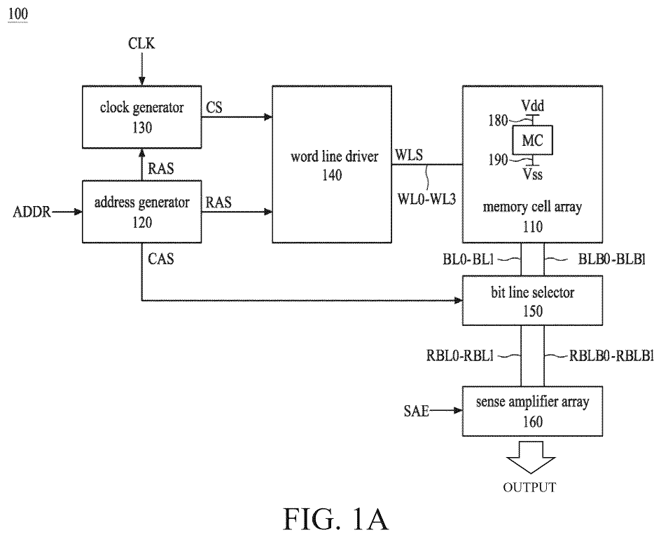

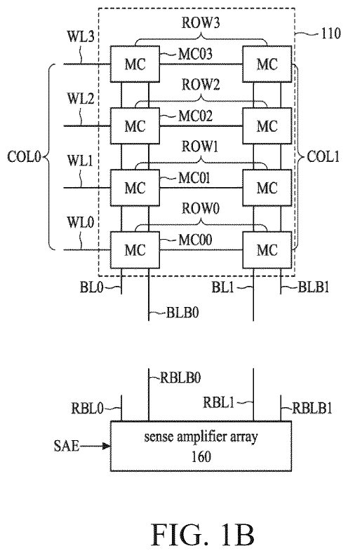

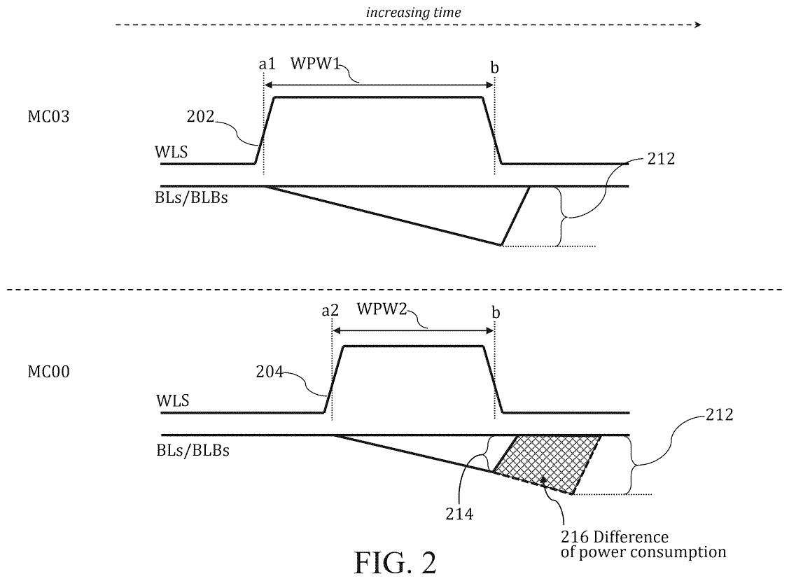

FIG. 1A is a schematic diagram of a memory device 100 according to an embodiment. FIG. 1B is a schematic diagram of a memory cell array 110 and a sense amplifier array 160 of FIG. 1A according to an embodiment. FIG. 2 is a graph of word line and bit line signals associated with the development of a differential bit line voltage and a related read margin.

Referring to FIG. 1A, a memory device 100 according to an embodiment includes a memory cell array 110 (which includes memory cells MC), an address generator 120, a clock generator 130, a word line driver 140, a bit line selector 150, and a sense amplifier (SA) array 160. The memory device 100 is configured to generate word line signals that have variable pulse widths.

In some embodiments, the memory device 100 is or includes one or more of a random-access memory (RAM) device (e.g., a static RAM (SRAM) or a dynamic RAM (DRAM) device), a read only memory (ROM) device, or the like. In some embodiments, each memory cell MC is configured to store bits, e.g., ‘1’ or ‘0’, of data therein.

For ease of explanation, an embodiment will now be described using an example of an SRAM memory in which memory cells are coupled to bit line pairs. In an embodiment, the memory cell MC is a six-transistor (6T) memory cell, i.e., includes six transistors. In some embodiments, the transistors are field effect transistors (FET) or other types of transistors. In some embodiments, the memory cells MC include other numbers of transistors. In some embodiments, another type of memory cell is used.

The memory cell array 110 includes a plurality of memory cells MC, each connected between a first supply terminal 180 and a second supply terminal 190. The first supply terminal 180 of the memory cell MC is coupled to a first supply voltage (e.g., Vdd) and the second supply terminal 190 is coupled to a second supply voltage (e.g., Vss). In an embodiment, the second supply voltage is lower than the first supply voltage. In some embodiments, Vdd is 0.3 V, 0.5 V, or another suitable voltage, and Vss is 0 V, −0.3 V, −0.5 V, or another suitable voltage.

The address generator 120 determines row addresses (which are used to determine which word line drivers to activate) based on an input signal ADDR. The address generator 120 outputs a row address signal RAS to the word line driver 140 and to the clock generator 130, and outputs a column address signal CAS to the bit line selector 150.

The clock generator 130 receives, as an input, an externally-supplied clock signal CLK. In an embodiment, the external clock signal CLK is input from a process outside the memory device 100 that synchronizes components of a processing device that utilizes memory device 100. The clock generator 130 generates an internal clock signal CS (also referred to herein as an internal clock signal CKP) based on the external clock signal CLK and the row address signal RAS, as described in further detail below.

The word line driver 140 generates word line signals WLS that have pulse widths WPW (see, e.g., FIG. 2). The word line driver 140 controls the pulse widths WPW according to a row address (also referred to herein as a word line address) of the memory cell MC in the memory cell array 110 to reduce power consumption of the memory device 100 in comparison with an approach using a uniform word line signal pulse width.

The bit line selector 150 is configured to select bit lines during read and/or write operations. The bit line selector 150 includes or is configured to operate as a read multiplexer (read mux). To read a memory cell MC (e.g., memory cell MC00 of FIG. 1B), the bit line selector 150 connects a bit line (BL) pair (e.g., a bit line/bit line bar pair BL0, BLB0), which is connected to the memory cell MC to be read (memory cell MC00), to a read bit line (RBL) pair (RBL/RBLB) (e.g., a read bit line/read bit line bar pair RBL0, RBLB0). Then, the word line driver 140 drives a word line (e.g., word line WL0) connected to the memory cell MC00 with a word line signal WLS having a pulse width WPW that is determined according to a row address of the memory cell MC00.

The sense amplifier array 160 receives a sense amplifier enable signal SAE. The sense amplifier array 160 includes an array of sense amplifiers SA coupled to the memory cell array 110. The sense amplifier array 160 includes sense amplifiers SA that are configured to be coupled to a corresponding bit line pair via the bit line selector 150. The sense amplifiers SA amplify a voltage difference sensed on the bit lines. This amplified sensed signal, representing the data (or bit) stored in each corresponding memory cell MC, is output to external processing circuits.

The memory cell array 110 includes a plurality of memory cells MC arranged in an array, by columns and rows. Each memory cell MC has a row address and a column address indicating position thereof in the array. The address generator 120 is configured to receive an input address signal ADDR, and to generate the column address signal CAS and the row address signal RAS corresponding to a selected memory cell MC.

The clock generator 130 generates and outputs the internal clock signal CS based on the externally-received clock signal CLK. In an embodiment, the external clock signal CLK is received from an external processing device, e.g., a processor, a system clock, or the like. In an embodiment, the internal clock signal CS has an amplitude that corresponds to an amplitude of the input clock signal CLK. The clock generator 130 receives the row address signal RAS from the address generator 120, and outputs the internal clock signal CS to the word line driver 140. As explained in further detail below, the clock generator 130 is configured to set a pulse width CPW of the internal clock signal CS based on the received row address signal RAS. The internal clock signal CS has a pulse width CPW that is varied depending on a row address of the memory cells MC.

The lengths of lines connecting the memory cells MC within the memory cell array 110 to a corresponding sense amplifier in the sense amplifier array 160 differ by row. That is, the lengths increase as the distance between a sense amplifier and a particular row of memory cells MC increases. As a length of a line increases, the RC characteristics of the line also increase. Thus, the amount of time for a bit line signal to develop on a bit line BL differs with the length of the bit line BL.

A memory that employs a single, uniform (i.e., unchanging) word line signal pulse width (e.g., a pulse width WPW that is long enough to ensure a valid read margin for those memory cells MC farthest from their corresponding sense amplifiers) can consume excess power when used for driving a memory cell MC having a short bit line BL. According to an embodiment, by tailoring the length (duration) of the word line signal pulse width WPW based on the row address of the memory cell MC (which relates to the length of the corresponding bit lines BL for a particular word line WL), the power consumed by the memory device 100 is reduced in comparison with an approach using a uniform word line signal pulse width. This is described in further detail below.

In FIG. 1B, a memory cell denoted MCmn (e.g., MC01, MC02, or the like) refers to a memory cell MC located in an m^{th} column (of columns 0 to m) and an n^{th} row (of rows 0 to n). Thus, memory cell MC01 is in COL0 and ROW1 of the memory cell array 110. In FIG. 1B, rows with lower numbers are closer to the sense amplifier array 160 than rows with higher numbers, with ROW3 being farthest from the sense amplifier array 160. In the memory cell array 110 in FIG. 1B, the memory cell MC03 is farther (more distant) from a corresponding sense amplifier in the sense amplifier array 160 than the memory cell MC00.

Each word line (WL0-WL3) is connected to the memory cells MC in a corresponding row (ROW0-ROW3). The word line driver 140 is coupled to the address generator 120, the clock generator 130, and the word lines (WL0-WL3). The word line driver 140 receives the row address signal RAS, which identifies or corresponds to the word line WL of the memory cell MC intended to be read. The word line driver 140 is configured to receive the internal clock signal CS that is generated by and output from the clock generator 130 and uses the internal clock signal CS to generate a word line signal WLS for a particular word line. The word line signal WLS has a pulse width WPW that corresponds to (e.g., is proportional to or the same as) a pulse width of the internal clock signal CS. Because clock generator 130 receives the row address signal RAS from address generator 120, it is able to generate the internal clock signal CS with a pulse width tailored to the intended word line WL addressed by the row address signal RAS. Word lines WL addressed by the row address signal RAS are driven with word line signals WLS having different pulse widths WPW according to different pulse widths of the internal clock signal CS, which are based on the row address signals RAS (i.e., the row addresses) of the word lines WL.

In FIGS. 1A and 1B, the memory device 100 includes bit line pair BL0, BLB0 and bit line pair BL1, BLB1, and read bit line pair RBL0, RBLB0 and read bit line pair RBL1, RBLB1. Each bit line pair (BL0, BLB0; BL1, BLB1) is connected to the memory cells MC in a corresponding column (COL0, COL1).

The bit line selector 150 is coupled to the address generator 120 and is further coupled between the bit line pairs (BL0, BLB0; BL1, BLB1) and the read bit line pairs (RBL0, RBLB0; RBL1, RBLB1). The bit line selector 150 is configured to receive the column address signal CAS, and to connect a read bit line pair to a bit line pair, whereby bits of data stored in a memory cell are transferred to the read bit line pair via the bit line pair.

The sense amplifier array 160 includes an array of sense amplifiers SA coupled to the read bit line pairs (RBL0, RBLB0; RBL1, RBLB1).

In FIG. 1B, there are two memory cells MC per word line WL, by way of example. In other embodiments, other numbers of memory cells MC (e.g., 2048, 4096, 8192, or the like) are included per word line WL. In FIG. 1B, the memory device 100 includes four rows ROW0-ROW3 and four word lines WL0-WL3 by way of example. In other embodiments, other numbers of rows and/or word lines (e.g., 128, 256, 512, 1024, or the like) are used. In FIG. 1B, the memory device 100 includes two columns COL0, COL1 by way of example. In other embodiments, other numbers of columns (e.g., 16, 32, 64, or the like) are used. FIGS. 1A and 1B include two bit line pairs and two read bit line pairs, by way of example. In other embodiments, other numbers of bit lines and/or read bit line pairs (e.g., 16, 32, 64, or the like) are included. In other embodiments, memory device 100 includes other numbers of memory cells MC, columns, rows or word lines, bit lines or bit line pairs, and read bit lines or read bit line pairs.

As described above, the length of a signal line affects the RC characteristics of that line, such that the rise times and fall times of voltages applied to those lines as signals can differ depending on a row location of a memory cell MC in the memory cell array 110. Memory cells MC for word lines WL that are closest to the sense amplifier array 160 have the shortest rise and fall times, and thus the shortest time to achieve a desired read margin, whereas memory cells MC for word lines WL that are farthest from the sense amplifier array 160 have the longest rise and fall times, and thus longest time to achieve a desired read margin. These differences in the voltage developing times to achieve a read margin are correlated to the row addresses of the memory cells MC, and pulse widths WPW of word line signals WLS are varied according to these differences in the voltage developing times, to thereby reduce power consumption of the memory device 100 in comparison with an approach using a uniform word line signal pulse width.

The sense amplifier array 160 is positioned relative to the memory cell array 110 such that the distance between a sense amplifier and a corresponding memory cell MC associated with that sense amplifier increases in a known or predictable manner, e.g., linearly, with increasing distance of the word line WL (or a word line group) from the sense amplifier array 160.

In FIG. 1B, the memory cells MC in ROW (e.g., memory cell MC00) are closer to the sense amplifier array 160 than the memory cells MC in ROW1 (e.g., memory cell MC01). Also, the memory cells MC in ROW2 (e.g., memory cell MC02) are closer to the sense amplifier array 160 than memory cells MC in ROW3 (e.g., memory cell MC03) but farther from the sense amplifier array 160 than the memory cells MC in ROW1 (e.g., memory cell MC01). As such, in a read operation, the rise time of memory cell MC03 is longer than the rise time of memory cell MC02, which is longer than the rise time of memory cell MC01, which is longer than the rise time of memory cell MC00. The pulse width WPW of the word line signal WLS applied to memory cell MC02 (and memory cells MC01, MC00) is shorter than the pulse width WPW of the word line signal WLS applied to memory cell MC03 while still achieving the same read margin. Thus, the power consumed in reading memory cell MC02 (and memory cells MC01, MC00) is reduced as compared to a device that applies a uniform pulse width to each word line WL. Similarly, the amount of time to read memory cell MC02 (and memory cells MC01, MC00) is shortened relative to memory cell MC03, thereby reducing an overall average time from the beginning of a read operation to a time that valid data is available.

FIG. 2 is a graph of a voltage difference developed on bit line/bit line bar pairs BLs/BLBs coupled to memory cells MC of different rows, according to an embodiment.

In FIG. 2, the pulse width of the word line signal WLS is varied by word line or groups of word lines, while maintaining sufficient development of voltages on the bit line/bit line bar pairs BLs/BLBs for all memory cells MC in the memory cell array 110 to be read accurately.

In FIG. 2, a word line signal WLS having a first pulse 202 with a corresponding first pulse width WPW1 is applied to a word line WL corresponding to memory cell MC03 in ROW3. A word line signal WLS having a second pulse 204 with a shorter-duration (relative to the first pulse width WPW1) second pulse width WPW2 is applied to a word line WL corresponding to memory cell MC00 in ROW0. Memory cell MC00 is closer to the sense amplifier array than memory cell MC03.

Timings ‘a1’, ‘a2’, and ‘b’ indicate the following: ‘a1’ and ‘a2’: word line signal (WLS) leading edge (rising edge) and start voltage difference on BLs/BLBs developing; ‘b’: WLS trailing edge (falling edge) and stop voltage difference on BLs/BLBs developing. Timing ‘b’ is subsequent in time to ‘a1’ and ‘a2’. The second pulse width WPW2 is made shorter, relative to the first pulse width WPW1, by controlling (particularly, delaying) the leading edge (or rising edge) of the word line signal pulse such that the leading edge of the second pulse 204 begins at a timing ‘a2’ that is delayed relative to ‘a1’, such that the duration (i.e., second pulse width WPW2) of the second pulse 204 from ‘a2’ to ‘b’ is shorter than the duration (i.e., first pulse width WPW1) of the first pulse 202 from ‘a1’ to ‘b’.

In FIG. 2, the word line pulse widths WPW are shown based on timings ‘a1’, ‘a2’, and ‘b’ that are located in the pulse edges. In other embodiments, the timings by which the duration of the pulse width WPW is defined are different, e.g., sooner or later in the leading or trailing edges (or rising or falling edges), from those shown in FIG. 2.

The first pulse width WPW1 applied to memory cell MC03 is controlled to be large enough (i.e., the first pulse 202 is long enough) that a developed voltage difference 212 on the bit line/bit line bar pairs BLs/BLBs for memory cell MC03 is sufficient to accurately read a stored value of memory cell MC03.

On the other hand, the second pulse width WPW2 of the second pulse 204 applied to memory cell MC00 is controlled to be shorter than the first pulse width WPW1. The second pulse width WPW2 is nonetheless large enough (i.e., the second pulse 204 is long enough) that a developed voltage difference 214 on the bit line/bit line bar pairs BLs/BLBs for memory cell MC00 is sufficient to accurately read a stored value of the memory cell MC00.

By reducing the pulse width WPW for the memory cell MC00, i.e., by applying the shorter duration second pulse 204 to the memory cell MC00, development of voltage difference 212 that substantially exceeds the voltage difference 214 is avoided for memory cell MC00, and power 216 that would otherwise be consumed by developing the voltage difference to the voltage difference 212 on the memory cell MC00 is conserved.

Stated differently, if the memory cell MC00 (which is closer to the sense amplifier array 160 than memory cell MC03) were to be read using the first pulse width WPW1, the voltage difference would develop more than needed to read the memory cell MC00 because the pulse width WPW1 is longer than the time for memory cell MC00 to develop the voltage difference 214 sufficient to read memory cell MC00.

Reading memory cells MC00, MC01, and MC02 using word line signals WLS having correspondingly shorter pulse widths conserves power, relative to an amount of power that would be expended in reading memory cells MC00, MC01, and MC02 using word line signals WLS having uniform pulse width for all rows.

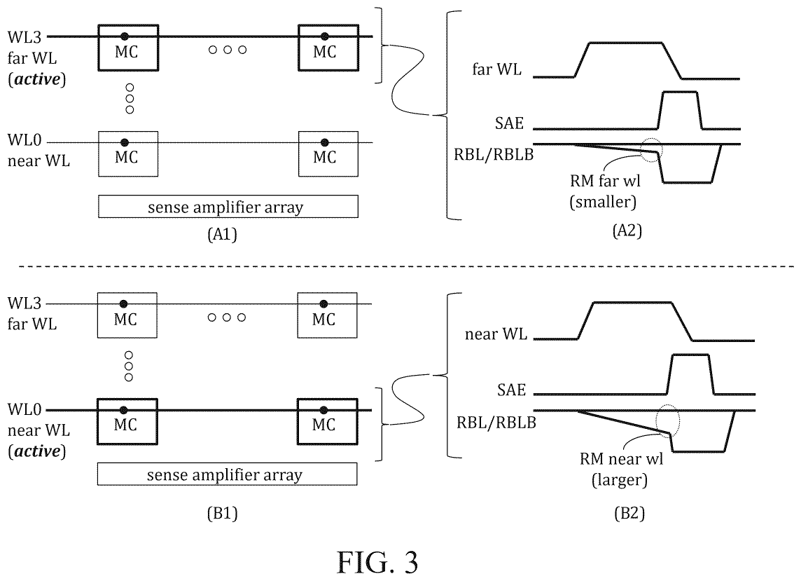

FIG. 3 is a graph of read margins in activated word lines that use varied word line pulse widths according to an embodiment.

The scenario in FIG. 3 generally corresponds to FIG. 2.

In FIG. 3, (A1) represents a read operation of a memory cell MC connected to a word line WL3 that is far from a sense amplifier array. Signals (A2) (word line, sense amplifier enable SAE, and read margin RM) correspond to (A1). Also, (B1) represents a read operation of a memory cell MC connected to a word line WL0 that is near to the sense amplifier array. Signals (B2) correspond to (B1).

In FIG. 3, a shorter word line pulse width is used for reading the near word line WL0, relative to a word line pulse width used for reading the far word line WL3. The shorter word line pulse width used for reading the word line WL0 has a leading edge that is delayed based on the address of the word line WL0. The word line pulse width is adjusted based on the row address and thus is longer for the far word line WL3 to account for greater physical resistance and capacitance of the longer bit line in a read operation on the far word line WL3 (signals (A2) of FIG. 3), but shorter for the near word line WL0 due to the lesser physical resistance and capacitance of the shorter bit line in a read operation on the near word line WL0 (signals (B2) of FIG. 3).

In FIG. 3, there is no substantial difference in read margin RM between (A2) showing the read margin RM for the far word line WL3 and (B2) showing the read margin RM for the near word line WL0 when the word line pulse width is varied according to the row address of the word line. That is, activation of the word line WL results in a same read margin RM for the near word line WL0 as for the far word line WL3. The size of the read margins RM for the far word line WL3 and the near word line WL0 are substantially the same because the word line pulse width is made shorter for the near word line WL0, based on the row address, in scenario (B1) of reading the near word line WL0 relative to the word line pulse width used in scenario (A1) of reading the far word line WL3.

The effect of using the different word line pulse widths based on the different row addresses of the far word line WL3 in scenario (A1) and the near word line WL0 in scenario (B1) is that word line activation power consumption is reduced for reading the near word line WL0 in signals (B2) relative to the power consumption for reading the far word line WL3 in signals (A2), thus reducing the overall power consumption of the memory.

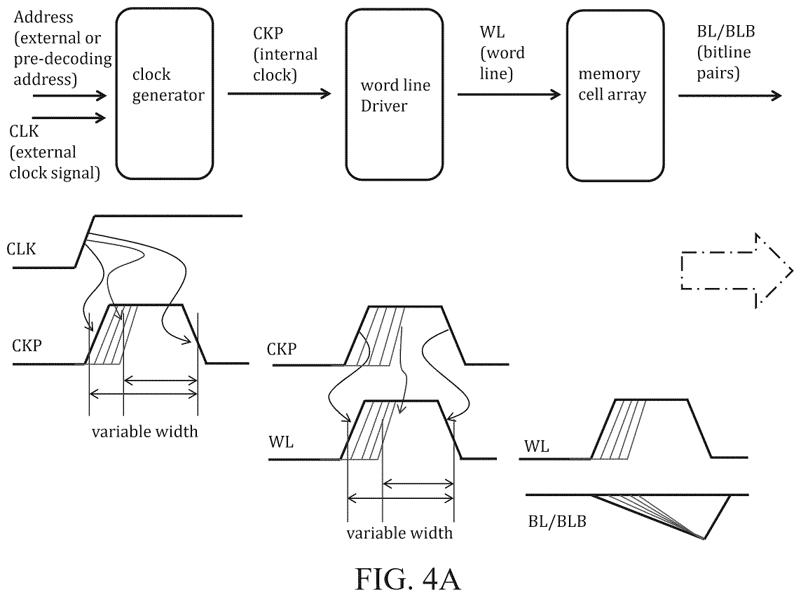

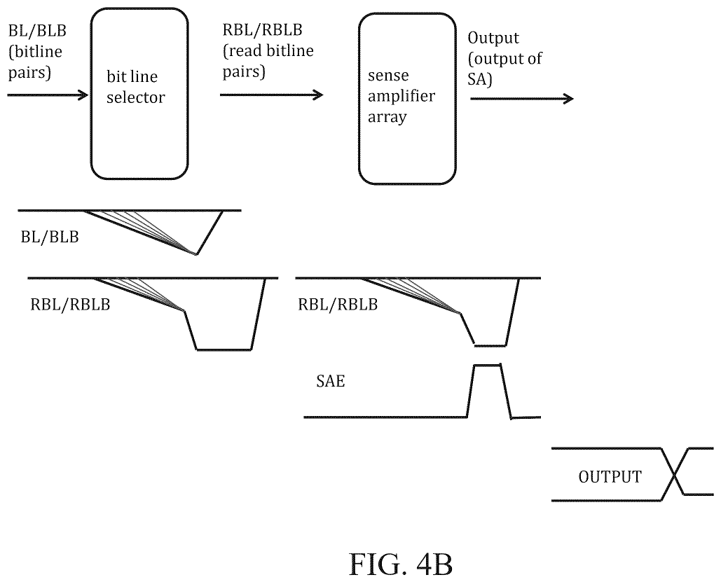

FIGS. 4A and 4B are sequential block diagrams and corresponding signals using varied internal clock signals to vary word line pulse widths according to an embodiment.

In the block diagrams, an address and an external clock signal CLK are input to a clock generator. In some embodiments, the address is an external address, a pre-decoding address, or the like. Based on the address and the external clock signal CLK, the clock generator generates and outputs an internal clock signal CKP (also referred to as the internal clock signal CS in FIG. 1) to a word line driver. The word line driver drives a word line WL of a memory cell array. The memory cell array is coupled by bit line pairs BL/BLB to a bit line selector (also referred to as a read multiplexer (MUX), or simply MUX). The bit line selector connects the bit line pairs BL/BLB to read bit line pairs RBL/RBLB. Thus, a memory cell MC (which is located in a row driven by the word line driver) is coupled to a sense amplifier in a sense amplifier array, which then outputs data read from the memory cell MC.

In the corresponding signals, the internal clock signal CKP that is generated based on the external clock signal CLK has a pulse width that is controlled based on the row address derived from the address signal. In detail, the leading edge (or rising edge) of the internal clock signal CKP is adjusted to be delayed (thus shortening the pulse width) for a row address of a row (or group of rows) that is nearer to the sense amplifier array, relative to a row address of a row (or group of rows) that is farther from the sense amplifier array.

Next, the word line is driven with a signal having a pulse width that depends on the pulse width of the internal clock signal CKP. Thus, a longer pulse width of the internal clock signal CKP results in a longer pulse width of the word line signal (for driving a word line that is relatively far from the sense amplifier array), whereas a shorter pulse width of the internal clock signal CKP results in a shorter pulse width of the word line signal (for driving a word line that is relatively near to the sense amplifier array). Delaying the leading edge (or rising edge) of the internal clock signal delays the leading edge (or rising edge) of the word line signal.

Next, the relatively shorter or longer pulse widths of the word line signal result in relatively shorter or longer developing time on the bit line pairs BL/BLB (FIG. 4A), which in turn lead to read margins on the read bit line pairs RBL/RBLB (FIG. 4B) that are more uniform (i.e., the same, or substantially the same) than for a case in which the word line signal has a same pulse width for all rows. That is, the read margins on the read bit line pairs RBL/RBLB are controlled to be the same (or closer to a same value) based on the address of the word line (or group of word lines). The read margin for a word line relatively near to the sense amplifier array is thus controlled to be the same as (or substantially the same as) a read margin for a word line relatively far from the sense amplifier array. This conserves power when reading data from the memory by not overdeveloping a voltage when reading a memory cell for the word line relatively near to the sense amplifier array, relative to an approach in which the word line signal has a same pulse width for all rows.

Finally, the sense amplifier enable signal SAE is input to the sense amplifier array to read a value in a memory cell MC and the value is output from the sense amplifier array.

In the above description and in the descriptions that follow, some embodiments are described in which a read margin RM is made to be the same for reading a word line WL that is relatively near to a sense amplifier SA as for reading a word line WL that is relatively far from a sense amplifier SA. In other embodiments, the read margin RM is made to be smaller (rather than the same) for reading the word line WL that is relatively near to the sense amplifier SA, relative to the read margin RM that would be obtained if using a far word line pulse width WPW on the near word line WL.

Also, in the above description and in the descriptions that follow, some embodiments are described in which the pulse width CPW of the internal clock signal CKP (or CS) and the pulse width WPW of the word line signal WLS are varied by row. In other embodiments, the pulse widths CPW and WPW are varied by groups of rows, e.g., the memory cell array may be driven with word line pulse widths WPW that correspond to two, four, eight, or the like groups of rows. That is, the number of different word line pulse widths WPW used in the memory is two, four, eight, or the like, in various embodiments.

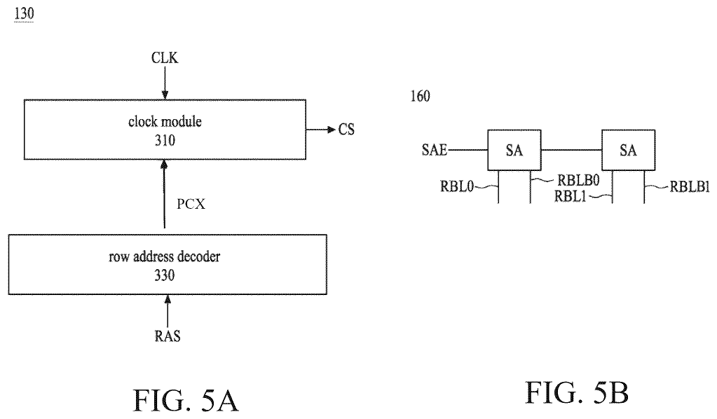

FIG. 5A is a schematic diagram of the clock generator 130 of FIG. 1A according to an embodiment.

In FIG. 5A, the clock generator 130 includes a clock module 310 and a row address decoder 330. The clock module 310 receives the input clock signal CLK. The clock module 310 generates and outputs an internal clock signal CS, timing of which is controlled depending on a row address of a memory cell MC to be read. Particularly, timing of the leading edge of the pulse of the internal clock signal CS is controlled depending on a row address of a memory cell MC to be read. In an embodiment, the internal clock signal CS has an amplitude that corresponds to, e.g., the same as, an amplitude of the input clock signal CLK. The clock module 310 is configured to vary or adjust a pulse width CPW of the internal clock signal CS depending on a row address of a memory cell MC to be read.

In the example of FIG. 5A, the row address decoder 330 receives the row address signal RAS, generates address-based signals PCX, and outputs the address-based signals PCX to the clock module 310.

FIG. 5B is a schematic diagram of a sense amplifier array 160 according to an embodiment.

The sense amplifier array 160 includes a plurality of sense amplifiers SA. In FIG. 5B, the two sense amplifiers SA correspond to the two memory cell column (e.g., COL0, COL1 in FIG. 1B), by way of example. In other embodiments, other numbers of sense amplifiers SA are used. In an embodiment, a sense amplifier SA is coupled to each bit line BL (or complementary bit line pair BL/BLB) between a column of memory cells and the sense amplifier array 160, and each read bit line pair (RBL0, RBLB0; RBL1, RBLB1) is coupled to a corresponding sense amplifier SA in the sense amplifier array 160.

In an embodiment, each sense amplifier SA is configured to amplify a voltage differential on a bit line pair in order to ensure that the voltage differential is sufficient to accurately represent a logic level (e.g., 0 or 1) of data in the corresponding memory cell MC. Each sense amplifier SA is further configured to receive a sense amplifier enable signal SAE that is timed to enable amplification while the word line is asserted causing a bit line voltage to develop. The sense amplifier SA amplifies the voltage difference sensed on the bit lines. Depending on whether the bit lines are single bit lines or complementary bit lines, in some embodiments, the sense amplifier SA is a differential sense amplifier and in other embodiments, the sense amplifier SA is a single-ended sense amplifier or other type of sense amplifier.

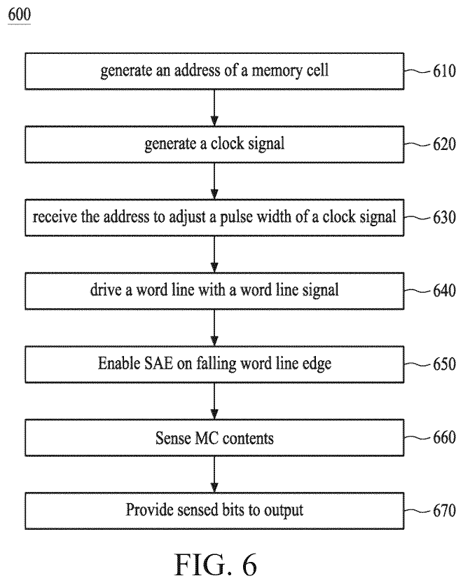

FIG. 6 is a flow chart of a method 600 of a read operation on a memory cell according to an embodiment.

Method 600 is described with reference to FIGS. 1A-5 for ease of understanding. However, method 600 is applicable to embodiments other than those of FIGS. 1A-5. In the read operation of method 600, an external circuit requests a read operation according to a read address corresponding to a memory cell in a memory cell array.

In operation 610, the address generator 120 receives an input address signal ADDR to generate the column and row address signals (CAS, RAS) of the memory cell to be read. The bit line selector 150 receives the column address signal CAS to connect the read bit line pair to the bit line pair.

Next, in operation 620, the clock generator 130 receives an input external clock signal CLK, and generates and outputs an internal clock signal CS. In an embodiment, the external clock signal CLK is derived in an external circuit supplied by a first power supply domain, and the internal clock signal CS is generated and output by clock generator 130 based on a power supply domain of the memory device 100. In an embodiment, the internal clock signal CS is generated with an amplitude that swings between a first supply voltage (e.g., Vdd) level and a second supply voltage (e.g., Vss) level.

In operation 630, the clock generator 130 receives the row address signal RAS, based on which the clock generator 130 generates an internal clock signal CS having a pulse width CPW adjusted for the intended word line of the memory cell to be read. The word line driver 140 receives the internal clock signal CS having the tailored pulse width CPW and generates a word line signal WLS having a word line pulse width WPW based on the pulse width CPW of the internal clock signal CS. This word line pulse width WPW is designed to allow for an appropriate amount of time for the read margin to develop on the read bit lines corresponding to the memory cell being read.

In operation 640, the word line driver 140 receives the row address signal RAS to drive the word line with the word line signal WLS having the pulse width WPW adjusted based on the internal clock signal CS pulse width CPW, which is adjusted based on the row address signal RAS. Upon assertion of the word line signal WLS for the word line, a corresponding read bit line pair develops a voltage differential corresponding to a value stored in the memory cell being read.

In operation 650, the sense amplifier enable SAE signal is asserted on the trailing edge (or falling edge) of the word line signal, causing the sense amplifier SA to amplify the voltage difference and allowing the contents of the memory cell to be sensed at operation 660 based on the voltage differential. For example, if a threshold voltage is exceeded, a bit value of 1 is sensed on the bit lines indicating a bit value of 1 is in the memory cell, and if the voltage does not exceed the threshold a bit value of 0 is sensed on the bit lines. It will be appreciated that, if the appropriate amount of time does not elapse, and the relevant voltages fail to develop on the bit lines, then accuracy of a read bit will degrade. However, asserting the word line signal for an excessive amount of time will cause the voltages to develop more than for an accurate read of the memory cell, and thus additional power is expended asserting the word line beyond the time to develop the threshold voltage, i.e., power is wasted. In some embodiments, the pulse width of the word line signal is tailored for each word line. In other embodiments, the pulse width of the word line signal is tailored for groups of multiple word lines.

In operation 660, data stored in the memory cell is sensed on the read bit line pair. Thereafter, at operation 670, data read from the memory cell is output.

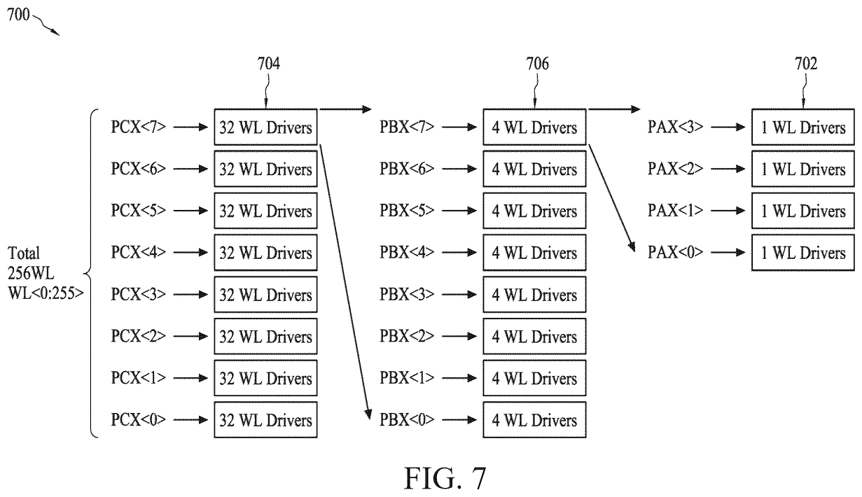

FIG. 7 is a block diagram of a word line addressing scheme 700 according to an embodiment.

In the addressing scheme 700, a memory cell array includes 256 word lines driven by 256 word line drivers 702, denoted WL<0:255> in FIG. 7. Each of the 256 word line drivers 702 is individually addressed using an address XA of eight bits. The 256 word line drivers are organized into eight groups 704 (each including thirty-two word line drivers 702, for driving thirty-two word lines), each organized into eight sub-groups 706. Each memory cell associated with a particular word line is considered to be the same distance from a corresponding sense amplifier, such that the length of any given bit line is considered to be the same for each memory cell associated with a particular word line. In FIG. 7, each memory cell associated with a same group 704 is provided with a same word line pulse width WPW.

In the addressing scheme 700, a pre-decoding rule is applied to eight-bit address XA (i.e., XA<0:7> to resolve address XA into three sub-addresses PAX, PBX, and PCX, as follows: XA<0:1>->PAX<0:3>; XA<2:4>->PBX<0:7>; and XA<5:7>->PCX<0:7>. The three most significant bits of address XA (i.e., XA<5:7>) correspond to one of eight word line driver groups 704, each addressed by PCX. Each word line driver group 704 includes eight word line driver sub-groups 706, each addressed by the second three most significant bits of XA as decoded to one of eight bits of PBX. Each sub-group 706 addressed by PBX includes four word line drivers 702, each addressed by the two least significant bits of XA as decoded to one of four bits of PAX. Thus, each of the eight groups of word line driver groups 704 addressed by PCX includes thirty-two word line drivers 702 for driving thirty-two word lines. Also, XA<5:7>->PCX<0:7> maps three bits of XA to the eight bits of PCX, and each bit of PCX addresses one word line driver group 704 corresponding to a same internal clock signal pulse width CPW and a corresponding word line signal pulse width WPW.

In an embodiment, the sub-address PCX has 8 bits (PCX<0:7>) that correspond to the three most significant bits of address XA (XA<5:7>). In an example, for the case XA<5:7>=<000>, PCX<0>=<00000001>. In another example, for the case XA<5:7>=<011>, PCX<3>=<00001000>. In another example, for the case XA<5:7>=<101>, PCX<5>=<00100000>. In another example, for the case XA<5:7>=<111>, PCX<7>=<10000000>.

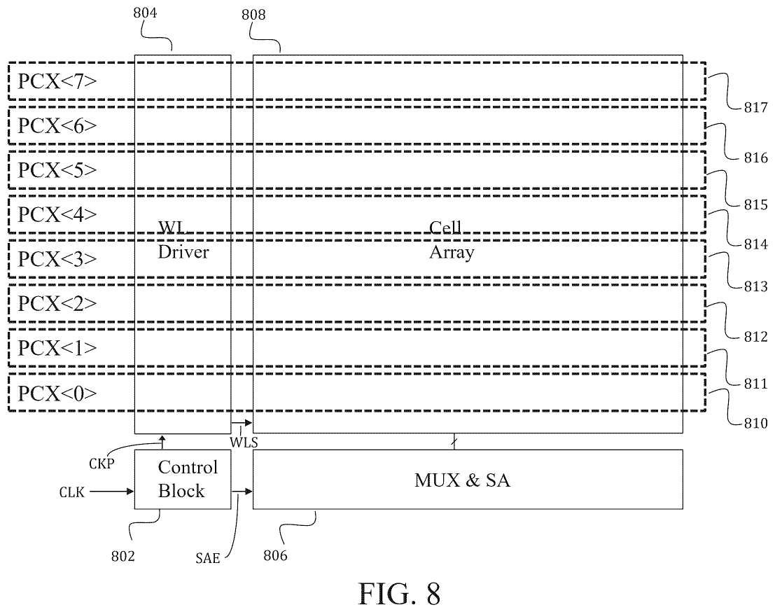

FIG. 8 is a block diagram of a memory device according to an embodiment.

In FIG. 8, an organizational scheme is described for a memory device having eight word line driver groups (i.e., word line driver group 810, word line driver group 811, . . . , word line driver group 817), each addressed (like word line group 704) by one bit from PCX<0> to PCX<7>, by way of example. In other embodiments, a memory device is assigned a number of word line driver groups that is more or less than eight. Each word line driver group 810-817 includes thirty-two word lines sub-addressed by bits PBX, PAX in similar manner to that shown in addressing scheme 700.

Each word line driver group 810-817 is addressed by one bit of PCX<0> to PCX<7> by the word line driver 804. Each group of word lines of word line driver groups 810-817 associated with each corresponding address bit PCX<0> to PCX<7> is increasingly far from MUX & sense amplifier (SA) components 806 in ascending order of PCX. That is, word lines of word line driver group 810, addressed by bit PCX<0>, are closer to MUX & SA components 806 than word lines of word line driver group 813 addressed by PCX<3>. Accordingly, each of the individual word lines in word line driver group 813, addressed by PCX<3>(and sub-addressed by PBX and PAX), takes a longer amount of time for the read margin to develop at MUX & SA components 806 than the word lines of word line driver groups 810-812, addressed by PCX<0>, PCX<1>, or PCX<2>.

In an embodiment, control block 802 receives external input signals (e.g., CLK or ADDR) and generates the internal clock signals (e.g., internal clock signal CS or CKP) and the sense amplifier enable signal SAE. In this example, the control block 802 generates an internal clock signal CKP having one of eight different pulse widths (each of the eight different pulse widths associated with each of the eight PCX addressable groups 810-817). The internal clock signal CKP is output from the control block 802 to the word line driver 804. The word line driver 804 generates word line signals WLS having different pulse widths WPW according to the different pulse widths CPW of the internal clock signal CKP, and thus according to the different word lines WL being addressed. The word line driver 804 outputs the word line signals WLS to memory cell array 808. The control block 802 is configured to assert a sense amplifier enable signal SAE (e.g., by asserting sense amplifier enable signal SAE on the trailing edge (or falling edge) of the WL signal) associated with each of the eight groups 810-817. The sense amplifier enable signal SAE is output from the control block 802 to the MUX & SA components 806. The MUX & SA components 806 read data from the memory cell array 808.

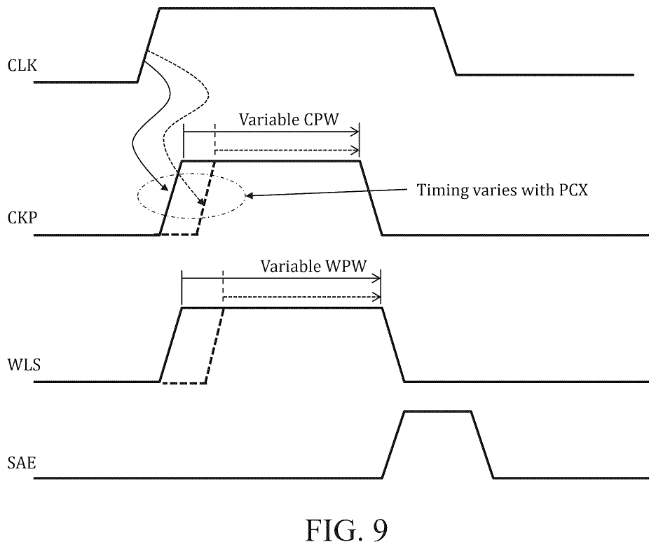

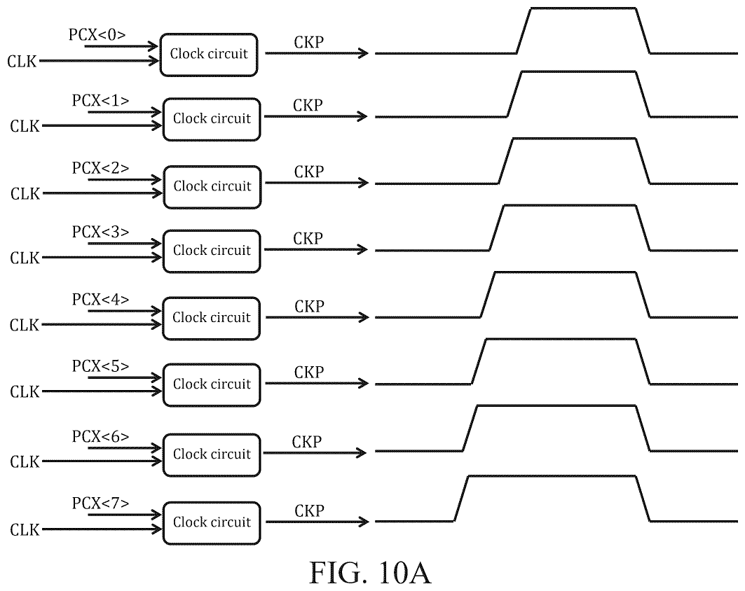

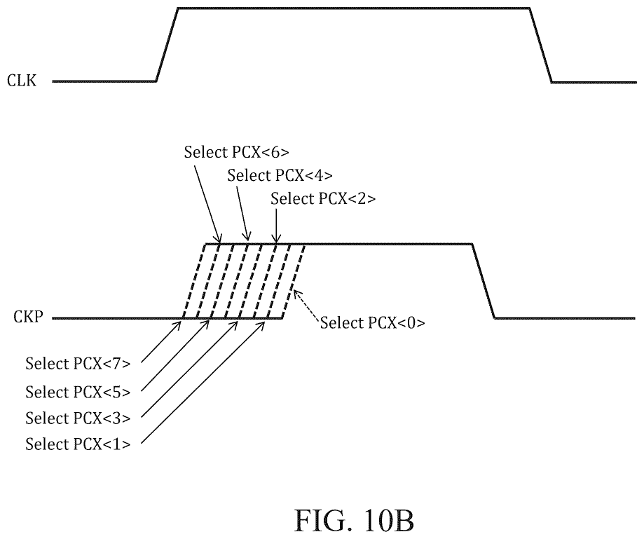

FIG. 9 is a graph of signals employed in driving a word line in a memory application according to an embodiment, and FIGS. 10A and 10B are block diagrams of a correspondence between row address-derived signals and internal clock signals according to an embodiment. FIG. 9 shows only two of eight internal clock signal and word line pulse widths of FIGS. 10A and 10B, merely by way of example, and for simplicity and clarity of explanation. In other embodiments, other numbers of pulse widths (e.g., two, four, eight, or the like) are used.

In an embodiment, external clock signal CLK is an externally-derived clock signal. Internal clock signal CKP is a clock signal generated for memory device operation control, and is generated by a suitable circuit, e.g., by the control block 802, by the clock generator 130, or by a circuit within word line driver 140. In an embodiment, the internal clock signal CKP is used as the internal clock signal CS described above.

In FIG. 9, the leading edge (or rising edge) of the internal clock signal CKP is generated with reference to the leading edge (or rising edge) of the external clock signal CLK. The pulse width CPW of the internal clock signal CKP is controlled (i.e., the internal clock signal pulse width CPW is made shorter or longer) using row address-derived signals PCX (e.g., PCX<0:7>) to change the timing of the leading edge (or rising edge) of the internal clock signal CKP (as shown in further detail in FIGS. 10A and 10B) relative to the leading edge (or rising edge) of the external clock signal CLK.

The word line signal WLS is generated such that the leading edge (or rising edge) of the word line signal WLS is generated with reference to the leading edge (or rising edge) of the internal clock signal CKP. Thus, the pulse width WPW of the word line signal WLS is controlled (i.e., the word line signal pulse width CPW is made shorter or longer) by the row address-derived signals PCX (e.g., PCX<0:7>). The trailing edge (or falling edge) of the word line signal WLS corresponds to the sense amplifier enable signal SAE.

In an embodiment, the word line signal WLS is generated based on internal clock signal CKP such that the pulse width WPW of the word line signal WLS is based on the pulse width CPW of the internal clock signal CKP. Thus, except for the possibility of small variations resulting from propagation, the pulse width WPW of the word line signal WLS is the same as the pulse width CPW of the internal clock signal CKP in some embodiments. In other embodiments, depending on design considerations, a delay is added to alter the pulse width WPW of the word line signal WLS relative to the pulse width CPW of the internal clock signal CKP.

Referring to FIGS. 10A and 10B, the leading edge of the internal clock signal CKP is controlled, based on signals PCX<0:7>, to be delayed relative to the leading edge of external clock signal CLK. In FIGS. 10A and 10B, PCX<7> corresponds to a longest pulse width of the internal clock signal CKP (for a row address corresponding to a word line farthest from the sense amplifier array) and signals PCX<0> corresponds to a shortest pulse width of the internal clock signal CKP (for a row address corresponding to a word line closest to the sense amplifier array).

In an embodiment, each increment/decrement in PCX<0:7>(i.e., PCX<0><->PCX<1>, PCX<1><->PCX<2>, or the like) corresponds to a uniform increment/decrement in the timing of the leading edge of the internal clock signal CKP. In another embodiment, the word line driver groups are not uniform in number word line drivers, and the increment/decrement in the timing is also not uniform.

In FIG. 10A, each signal of signals PCX<0:7> is supplied to an individual clock circuit for clarity and ease of explanation. In some embodiments, a single clock circuit is used.

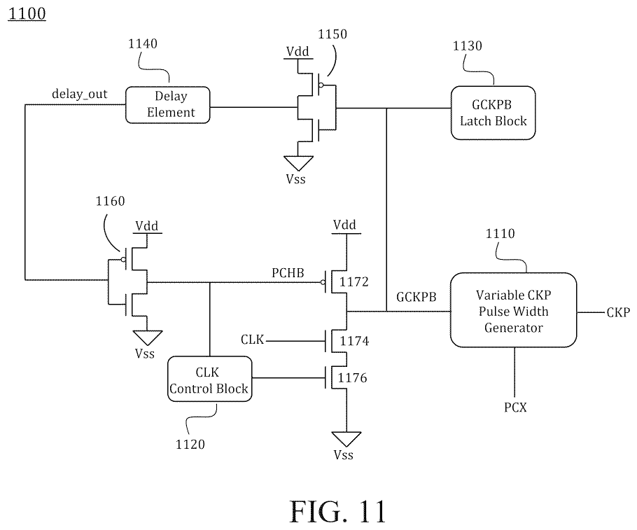

FIG. 11 is a schematic diagram of an internal clock signal generator circuit 1100 that generates an internal clock signal CKP having a variable pulse width CPW, according to an embodiment.

Referring to FIG. 11, internal clock signal generator circuit 1100 generates the internal clock signal CKP to have a pulse width CPW that is controlled based on a memory cell row address, which is decoded into a plurality of signals PCX. The variable internal clock signal pulse width generator 1110 receives the row address-derived signals PCX and outputs the internal clock signal CKP. The variable internal clock signal pulse width generator 1110 varies timing of the leading edge (or rising edge) of the internal clock signal CKP to thereby control the pulse width CPW of the internal clock signal CKP, which in turn is used to vary the timing of the leading edge (or rising edge) of the word line signal WLS to thereby control the pulse width WPW of the word line signal WLS, as described above in connection with FIG. 9.

In an embodiment, the internal clock signal CKP is used as the internal clock signal CS described above in connection with FIG. 1. In an embodiment, the internal clock signal generator circuit 1100 is included in the clock generator 130 of FIG. 1. In an embodiment, the internal clock signal generator circuit 1100 is included in the clock module 310 of FIG. 5A. In other embodiments, the internal clock signal generator circuit 1100 or a similar circuit is included in the word line driver 140 or another element of the memory device 100.

In internal clock signal generator circuit 1100, the variable internal clock signal pulse width generator 1110 is coupled to a GCKPB latch block 1130, a node between terminals of a first transistor 1172 and a second transistor 1174 (which are connected in series), and the gate of a third transistor 1150. The internal clock signal generator circuit 1100 also includes a delay element 1140 coupled between a terminal of the third transistor 1150 and the gate of a fourth transistor 1160, and a clock signal CLK control block 1120 coupled between a terminal of the fourth transistor 1160 and the gate of a fifth transistor 1176, which is coupled in series with the second transistor 1174. The second transistor 1174 receives, at the gate thereof, the external clock signal CLK. The delay element 1140 is configured to lengthen the pulse width of signal GCKPB and thus also lengthen the pulse width WPW of the word line signal WLS to provide a basic word line signal WLS pulse width.

When the external clock signal CLK goes high, signal GCKPB is pulled low through the second transistor 1174, which pulls delay_out high through the third transistor 1150 and delay element 1140, which turns off the fourth transistor 1160, pulling signal PCHB high. Also when GCKPB is pulled low, the internal clock signal CKP is pulled high via the internal clock signal pulse width generator 1110, creating a rising edge of the internal clock signal CKP. When the external clock signal CLK goes low and GCKPB is pulled high again (through the first transistor 1172), it pulls the internal clock signal CKP low via the internal clock signal pulse width generator 1110, i.e., creates a falling edge of the internal clock signal CKP.

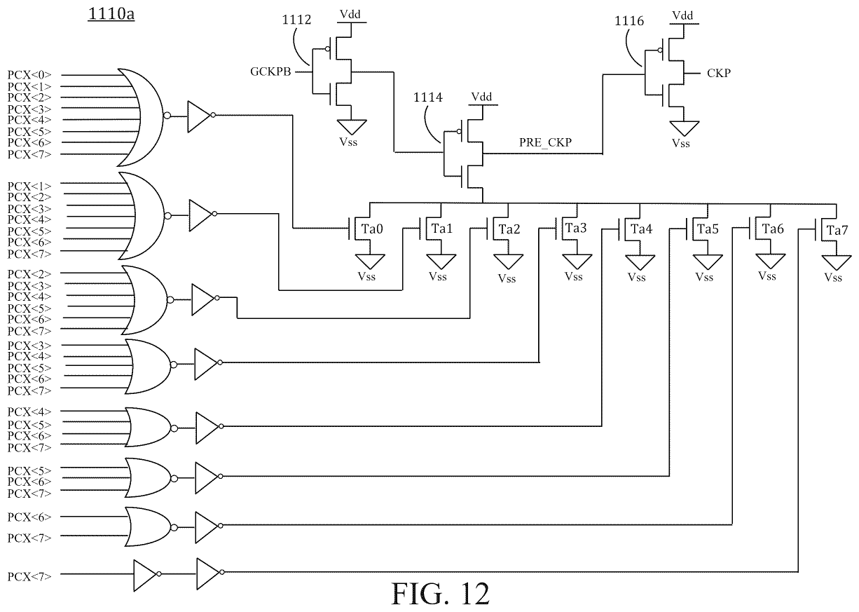

Examples of the variable internal clock signal pulse width generator 1110 will now be described in connection with FIGS. 12-31.

FIG. 12 is a schematic diagram of a variable internal clock signal pulse width generator 1110a according to an embodiment.

In FIG. 12, the variable internal clock signal pulse width generator 1110a receives row address-derived signals PCX<0:7> and the internal signal GCKPB (see FIG. 11), and outputs the internal clock signal CKP having a pulse width CPW that varies based on the row address-derived signals PCX<0:7>.

In detail, in the variable internal clock signal pulse width generator 1110a, inverters 1112, 1114, and 1116 are coupled in stages, with the output of inverter 1112 coupled to the input of inverter 1114, and the output of inverter 1114 coupled to the input of inverter 1116. The internal signal GCKPB is input to inverter 1112, and the internal clock signal CKP is output from inverter 1116. In FIG. 12, a signal PRE_CKP, which is output from the inverter 1114 to the inverter 1116, is varied based on the row address-derived signals PCX<0:7> using eight transistors Ta0, Ta1, . . . , Ta7 that control a connection between a terminal of the inverter 1114 and the second supply voltage Vss. Gates of the transistors Ta0, Ta1, . . . , Ta7 are controlled using the row address-derived signals PCX<0:7>.

In the embodiment of FIG. 12, the signal PCX<7> corresponds to the internal clock signal CKP having the longest pulse width CPW, and the signal PCX<0> corresponds to the internal clock signal CKP having the shortest pulse width CPW, as shown in FIGS. 10A and 10B.

In FIG. 12, eight groups of the signals PCX<0:7>(each group including incrementally fewer of signals PCX<0:7>) are input to eight corresponding logic Not Or (NOR) gates. Outputs of the eight NOR gates are input to corresponding inverters, which are coupled to corresponding gates of the eight transistors Ta0, Ta1, . . . , Ta7. Thus, a first group of eight signals PCX<0:7> is input to a first NOR gate, a second group of seven signals PCX<1:7> is input to a second NOR gate, a third group of six signals PCX<2:7> is input to a third NOR gate, and so on, with an eighth group of one signal PCX<7> being input to an eighth NOR gate.

For PCX<0>=<00000001>, the first NOR gate (which receives all of PCX<0:7>) outputs logic ‘0’, which is inverted by the inverter to turn on transistor Ta0. In the same manner, the transistor Ta0 will be turned on for any of PCX<0:7>.

For PCX<3>=<00001000>, the first through fourth NOR gates (which each receive PCX<3>) output logic ‘0’, which is inverted by the corresponding inverters to turn on transistors Ta0, Ta1, Ta2, and Ta3. The fifth through eighth NOR gates do not receive PCX<3>.

For PCX<5>=<00100000>, the first through sixth NOR gates (which each receive PCX<5>) output logic ‘0’, which is inverted by the corresponding inverters to turn on transistors Ta0, Ta1, Ta2, Ta3, Ta4, and Ta5.

The eighth NOR gate receives only PCX<7>(<10000000>) and thus the transistor Ta7 is only turned on for PCX<7>.

The transistors are thus controlled to be turned on by the signals PCX<0:7> as shown in Table 1:

TABLE 1

| PCX<0:7> | On |
|---|---|
| PCX<0> = <00000001> | Ta0 |
| PCX<1> = <00000010> | Ta0, Ta1 |
| PCX<2> = <00000100> | Ta0, Ta1, Ta2 |
| PCX<3> = <00001000> | Ta0, Ta1, Ta2, Ta3 |
| PCX<4> = <00010000> | Ta0, Ta1, Ta2, Ta3, Ta4 |
| PCX<5> = <00100000> | Ta0, Ta1, Ta2, Ta3, Ta4, Ta5 |
| PCX<6> = <01000000> | Ta0, Ta1, Ta2, Ta3, Ta4, Ta5, Ta6 |
| PCX<7> = <10000000> | Ta0, Ta1, Ta2, Ta3, Ta4, Ta5, Ta6, Ta7 |

In FIG. 12, turning on a greater number of the transistors Ta0, Ta1, . . . , Ta7 makes the slope of signal PRE_CKP relatively sharper (or steeper) and turning on a smaller number of the transistors Ta0, Ta1, . . . , Ta7 makes the slope of signal PRE_CKP relatively shallower (or less sharp or steep). A sharper (or steeper) slope of signal PRE_CKP results in an earlier leading edge of the internal clock signal CKP, and thus a longer pulse width CPW of the internal clock signal and a longer pulse width WPW of the word line signal WLS. Conversely, a shallower (or less sharp or steep) slope of signal PRE_CKP results in a later leading edge of the internal clock signal CKP, and thus a shorter pulse width CPW of the internal clock signal and a shorter pulse width WPW of the word line signal WLS.

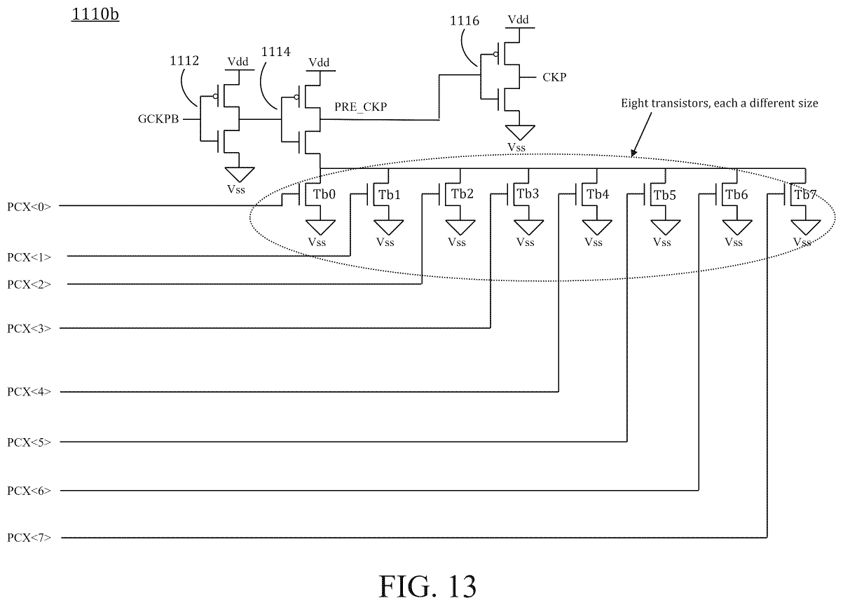

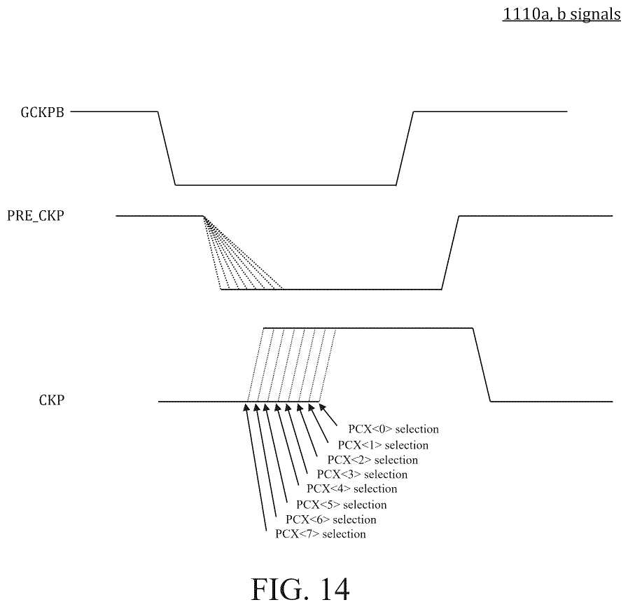

FIG. 13 is a schematic diagram of a variable internal clock signal pulse width generator 1110b according to an embodiment.

In FIG. 13, in the same manner as in FIG. 12, the variable internal clock signal pulse width generator 1110b receives row address-derived signals PCX<0:7> and the internal signal GCKPB, and outputs the internal clock signal CKP having a pulse width CPW that varies based on the row address-derived signals PCX<0:7>. Also in FIG. 13, in the same manner as in FIG. 12, eight transistors Tb0, Tb1, . . . , Tb7 control a connection between a terminal of the inverter 1114 and the second supply voltage Vss.

On the other hand, in FIG. 13, unlike in FIG. 12, NOR gates and corresponding inverters are not included. Instead, each of signals PCX<0:7> is provided to a corresponding one of transistors Tb0, Tb1, . . . , Tb7. The transistors Tb0, Tb1, . . . , Tb7 are each a different size with progressively larger sizes (i.e., transistor Tb0 is the smallest and transistor Tb7 is the largest), with a larger size transistor making the slope of signal PRE_CKP relatively sharper (or steeper) and a smaller size transistor making the slope of signal PRE_CKP relatively shallower (or less sharp or steep).

In FIG. 13, turning on a larger transistor makes the slope of signal PRE_CKP relatively sharper (or steeper) and turning on a smaller transistor makes the slope of signal PRE_CKP relatively shallower (or less sharp or steep). A sharper (or steeper) slope of signal PRE_CKP results in an earlier leading edge of the internal clock signal CKP and thus a longer pulse width CPW of the internal clock signal and a longer pulse width WPW of the word line signal WLS. Conversely, a shallower (or less sharp or steep) slope of signal PRE_CKP results in a later leading edge of the internal clock signal CKP and thus a shorter pulse width CPW of the internal clock signal and a shorter pulse width WPW of the word line signal WLS.

In an embodiment, the different sizes of the transistors refers to different width-to-length (W/L) ratios of the transistors. In an embodiment, the different sizes of the transistors refers to different channel resistances and/or gate capacitances of the transistors. In an embodiment, the different sizes of the transistors refers to a different current flow of the transistors when activated.

FIG. 14 is a graph of signals GCKPB, PRE_CKP, and CKP corresponding to the variable internal clock signal pulse width generators 1110a and 1110b of FIGS. 12 and 13.

In FIG. 14, the signal PCX<7> corresponds to the internal clock signal CKP having the longest pulse width, and the signal PCX<0> corresponds to the internal clock signal CKP having the shortest pulse width, as shown in FIGS. 10A and 10B. The timing of the leading edge (or rising edge) of internal clock signal CKP based on the sharper or shallower slope of signal PRE_CKP, which is controlled by transistors Ta0, Ta1, . . . , Ta7 in FIG. 12 or by transistors Tb0, Tb1, . . . , Tb7 in FIG. 13. For example, the signal PCX<7> corresponds to the sharpest slope of signal PRE_CKP, which is due to all of transistors Ta0, Ta1, . . . , Ta7 being turned on in FIG. 12, and due to the largest transistor Tb7 being turned on in FIG. 13.

In some embodiments, the pulse width CPW of the internal clock signal CKP is controlled to be longer or shorter by controlling steepness of the slope of the leading edge of signal PRE_CKP (or by controlling the steepness of the slope of the leading edge of signal POST_GCKPB, as below) using the variable internal clock signal pulse width generator 1110. In other embodiments, another element or other elements of the internal clock signal generator circuit 1100 are controlled (either instead of or in addition to the variable internal clock signal pulse width generator 1110) based on a row address or a signal derived from the row address.

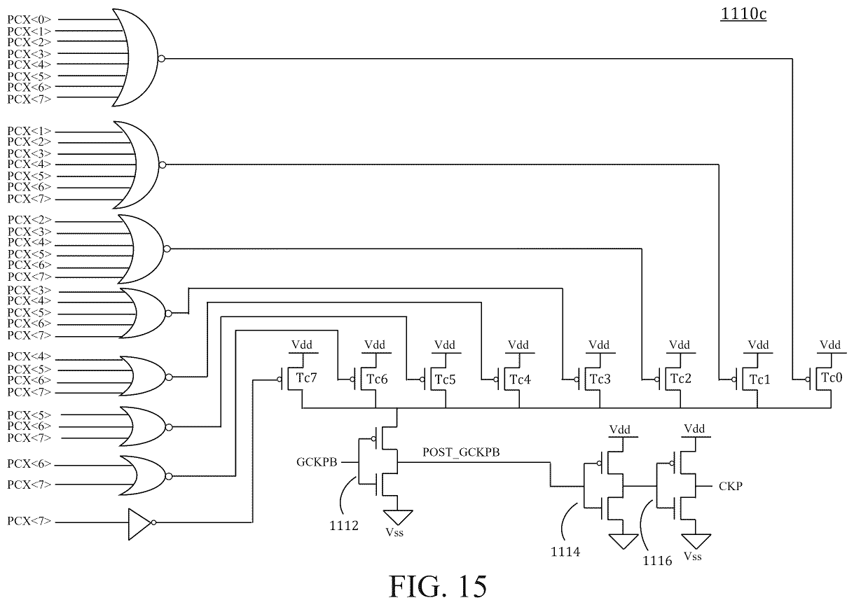

FIG. 15 is a schematic diagram of a variable internal clock signal pulse width generator 1110c according to an embodiment.

In FIG. 15, the variable internal clock signal pulse width generator 1110c receives row address-derived signals PCX<0:7> and the internal signal GCKPB, and outputs the internal clock signal CKP having a pulse width CPW that varies based on the row address-derived signals PCX<0:7>.

In detail, in the variable internal clock signal pulse width generator 1110c, inverters 1112, 1114, and 1116 are coupled in stages, with the output of inverter 1112 coupled to the input of inverter 1114, and the output of inverter 1114 coupled to the input of inverter 1116. The internal signal GCKPB is input to inverter 1112, and the internal clock signal CKP is output from inverter 1116.

In FIG. 15, a signal POST_GCKPB, which is output from the inverter 1112 to the inverter 1114, is varied based on the row address-derived signals PCX<0:7> using eight transistors Tc0, Tc1, . . . , Tc7 that control a connection between the first supply voltage Vdd and a terminal of the inverter 1112. Gates of the transistors Tc0, Tc1, . . . , Tc7 are controlled using the row address-derived signals PCX<0:7>, such that the signal PCX<7> corresponds to the internal clock signal CKP having the longest pulse width, and the signal PCX<0> corresponds to the internal clock signal CKP having the shortest pulse width.

In FIG. 15, turning on a greater number of the transistors Tc0, Tc1, . . . , Tc7 makes the slope of signal POST_GCKPB relatively sharper (or steeper) and turning on a smaller number of the transistors Tc0, Tc1, . . . , Tc7 makes the slope of signal POST_GCKPB relatively shallower (or less sharp or steep). A sharper (or steeper) slope of signal POST_GCKPB results in an earlier leading edge of the internal clock signal CKP, and thus a longer pulse width CPW of the internal clock signal and a longer pulse width WPW of the word line signal WLS. Conversely, a shallower (or less sharp or steep) slope of signal POST_GCKPB results in a later leading edge of the internal clock signal CKP, and thus a shorter pulse width CPW of the internal clock signal and a shorter pulse width WPW of the word line signal WLS.

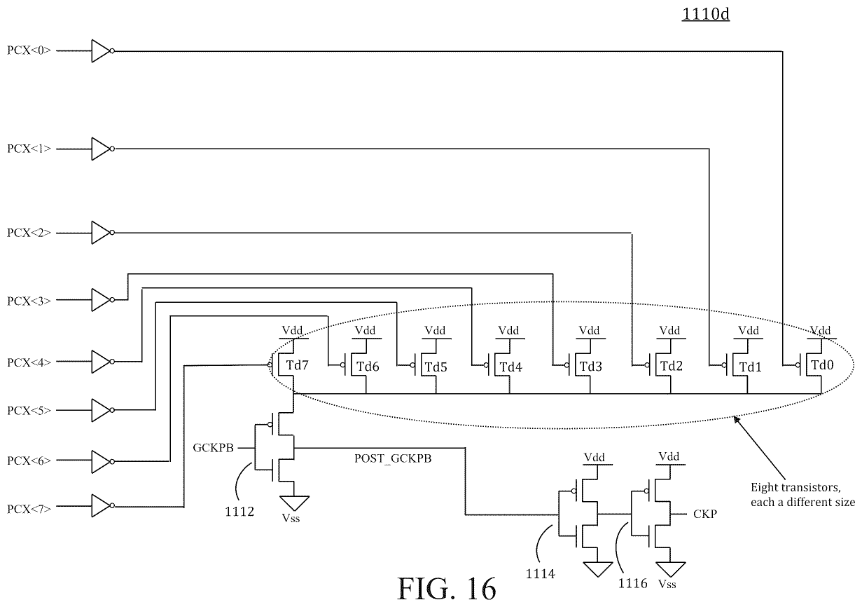

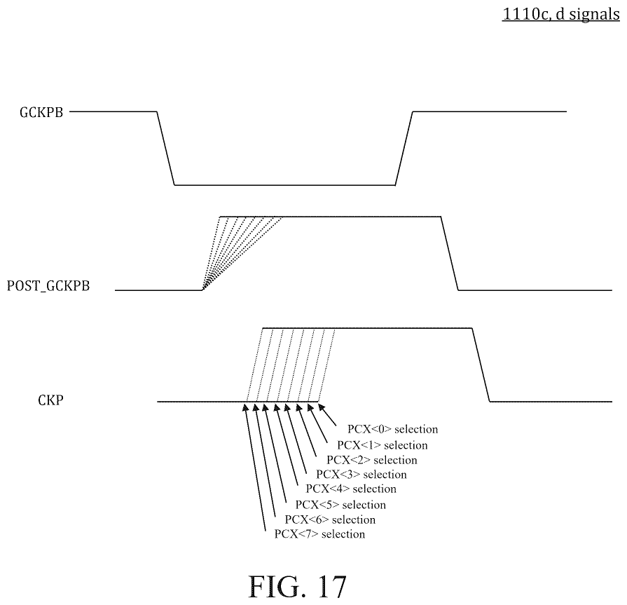

FIG. 16 is a schematic diagram of a variable internal clock signal pulse width generator 1110d according to an embodiment.

In FIG. 16, the variable internal clock signal pulse width generator 1110d receives row address-derived signals PCX<0:7> and the internal signal GCKPB, and outputs the internal clock signal CKP having a pulse width that varies based on the row address-derived signals PCX<0:7>. Also in FIG. 16, in the same manner as in FIG. 15, eight transistors Td0, Td1, . . . , Td7 control a connection between the first supply voltage Vdd and a terminal of the inverter 1112.

In FIG. 16, NOR gates and corresponding inverters are not included. Instead, each of signals PCX<0:7> is provided to a corresponding one of transistors Td0, Tb1, . . . , Td7. The transistors Td0, Td1, . . . , Td7 are each a different size with progressively larger sizes (i.e., transistor Td0 is the smallest and transistor Td7 is the largest), with a larger size transistor making the slope of signal POST_GCKPB relatively sharper (or steeper) and a smaller size transistor making the slope of signal POST_GCKPB relatively shallower (or less sharp or steep). A sharper (or steeper) slope of signal POST_GCKPB results in an earlier leading edge of the internal clock signal CKP and thus a longer pulse width CPW of the internal clock signal and a longer pulse width WPW of the word line signal WLS. Conversely, a shallower (or less sharp or steep) slope of signal POST_GCKPB results in a later leading edge of the internal clock signal CKP and thus a shorter pulse width CPW of the internal clock signal and a shorter pulse width WPW of the word line signal WLS.

FIG. 17 is a graph of signals GCKPB, POST_GCKPB, and CKP corresponding to the variable internal clock signal pulse width generators 1110c and 1110d of FIGS. 15 and 16.

In FIG. 17, the signal PCX<7> corresponds to the internal clock signal CKP having the longest pulse width, and the signal PCX<0> corresponds to the internal clock signal CKP having the shortest pulse width. The timing of the leading edge (or rising edge) of internal clock signal CKP is based on the sharper or shallower slope of signal POST_GCKPB, which is controlled by transistors Tc0, Tc1, . . . , Tc7 in FIG. 15, or transistors Tc0, Tc1, . . . , Tc7 in FIG. 16. For example, the signal PCX<7> corresponds to the sharpest slope of signal POST_GCKPB.

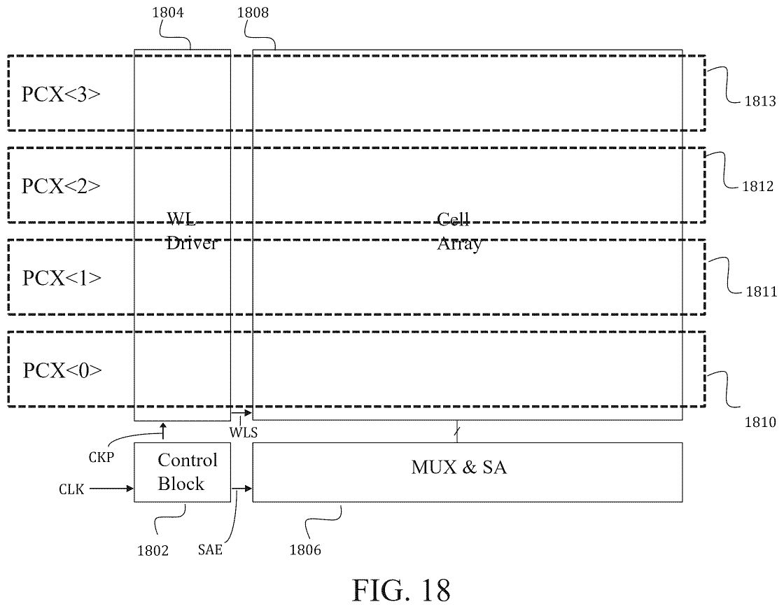

FIG. 18 is a block diagram of a memory device according to an embodiment.

In FIG. 18, an organizational scheme is described for a memory device having four word line driver groups 1810-1813, each addressed by one bit from PCX<0> to PCX<3>, by way of example. Each group of word lines of word line driver groups 1810-1813 associated with each address bit PCX<0> to PCX<3> is increasingly far from MUX & sense amplifier (SA) components 1806 in ascending order of PCX. That is, word lines of word line driver group 1810, addressed by bit PCX<0>, are closer to MUX & SA components 1806 than word lines of word line driver group 1813 addressed by PCX<3>. Accordingly, each of the individual word lines in word line driver group 1813, addressed by PCX<3>, takes a longer amount of time for the read margin to develop at MUX & SA components 1806 than the word lines of word line driver groups 1810-1812, addressed by PCX<0>, PCX<1>, or PCX<2>.

In an embodiment, control block 1802 receives external input signals (e.g., CLK or ADDR) and generates the internal clock signals (e.g., internal clock signal CS or CKP) and the sense amplifier enable signal SAE. In this example, the control block 1802 generates an internal clock signal CKP having one of four different pulse widths (each of the four different pulse widths associated with each of the four PCX addressable groups 1810-1813). The internal clock signal CKP is output from the control block 1802 to the word line driver 1804. The word line driver 1804 generates word line signals WLS having different pulse widths WPW according to the different pulse widths of the internal clock signal CKP, and thus according to the different word lines WL being addressed. The word line driver 1804 outputs the word line signals WLS to memory cell array 1808. The control block 1802 is configured to assert a sense amplifier enable signal SAE (e.g., by asserting sense amplifier enable signal SAE on the trailing edge (or falling edge) of the WL signal) associated with each of the four groups 1810-1813. The sense amplifier enable signal SAE is output from the control block 1802 to the MUX & SA components 1806. The MUX & SA components 1806 read data from the memory cell array 1808.

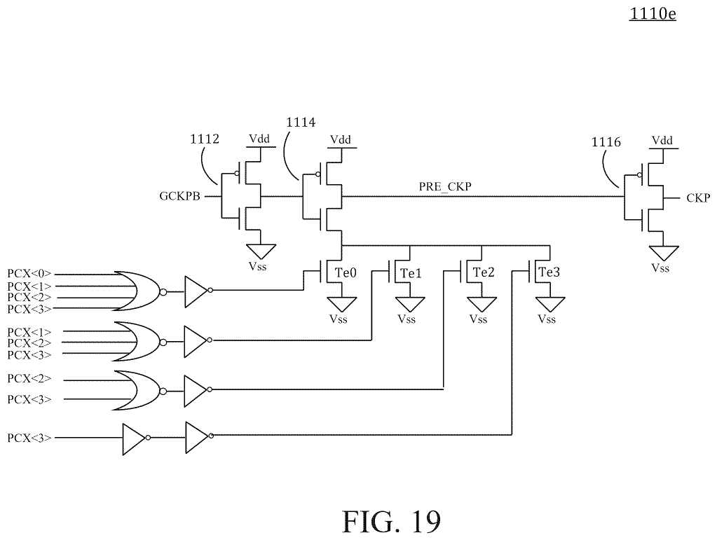

FIG. 19 is a schematic diagram of a variable internal clock signal pulse width generator 1110e according to an embodiment.

In FIG. 19, the variable internal clock signal pulse width generator 1110e receives row address-derived signals PCX<0:3> and the internal signal GCKPB, and outputs the internal clock signal CKP having a pulse width that varies based on the row address-derived signals PCX<0:3>.

In detail, in the variable internal clock signal pulse width generator 1110e, inverters 1112, 1114, and 1116 are coupled in stages, with the output of inverter 1112 coupled to the input of inverter 1114, and the output of inverter 1114 coupled to the input of inverter 1116. The internal signal GCKPB is input to inverter 1112, and the internal clock signal CKP is output from inverter 1116.

In FIG. 19, a signal PRE_CKP, which is output from the inverter 1114 to the inverter 1116, is varied based on the row address-derived signals PCX<0:3> using four transistors Te0, Te1, Te2, Te3 that control a connection between a terminal of the inverter 1114 and the second supply voltage Vss. Gates of the transistors Te0, Te1, Te2, Te3 are controlled using the row address-derived signals PCX<0:3> in a manner similar to that described above in connection with FIG. 12, such that the signal PCX<3> corresponds to the internal clock signal CKP having the longest pulse width, and the signal PCX<0> corresponds to the internal clock signal CKP having the shortest pulse width.

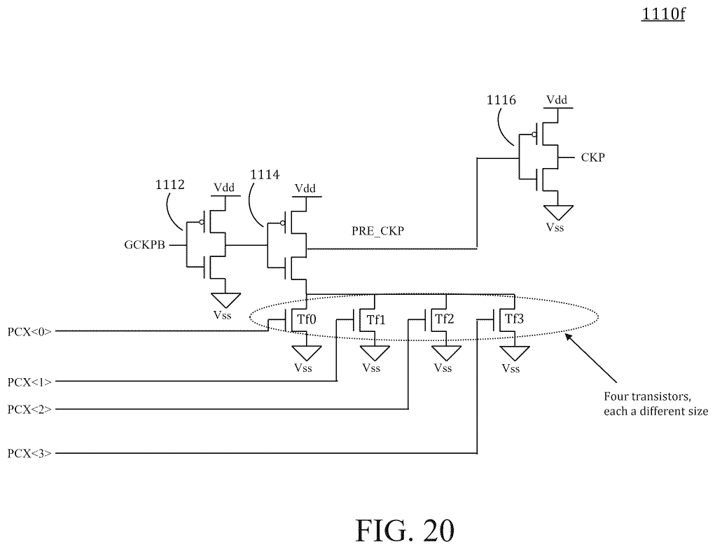

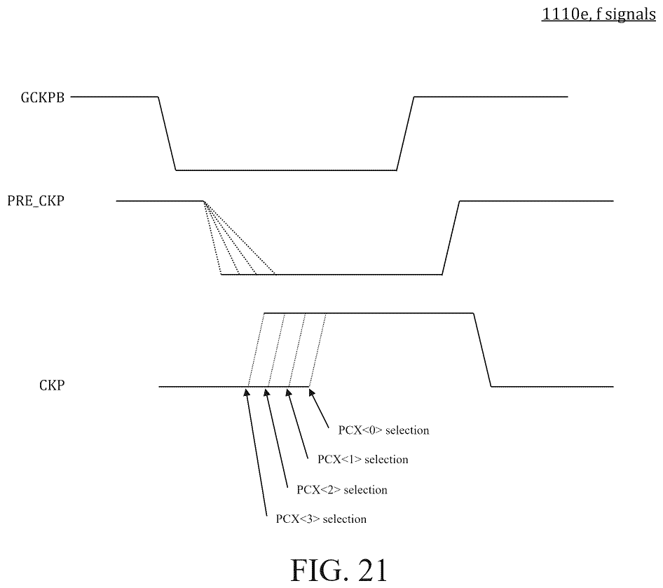

FIG. 20 is a schematic diagram of a variable internal clock signal pulse width generator 1110f according to an embodiment.

In FIG. 20, the variable internal clock signal pulse width generator 1110f receives row address-derived signals PCX<0:3> and the internal signal GCKPB, and outputs the internal clock signal CKP having a pulse width that varies based on the row address-derived signals PCX<0:3>. Also in FIG. 20, in the same manner as in FIG. 19, four transistors Tf0, Tf1, Tf2, Tf3 control a connection between a terminal of the inverter 1114 and the second supply voltage Vss.

In FIG. 20, NOR gates and corresponding inverters are not included. Instead, each of signals PCX<0:3> is provided to a corresponding one of transistors Tf0, Tf1, Tf2, Tf3. The transistors Tf0, Tf1, Tf2, Tf3 are each a different size with progressively larger sizes. That is, transistor Tf0 is the smallest and transistor Tf3 is the largest.

FIG. 21 is a graph of signals GCKPB, PRE_CKP, and CKP corresponding to the variable internal clock signal pulse width generators 1110e and 1110f of FIGS. 19 and 20.

In FIG. 21, the signal PCX<3> corresponds to the internal clock signal CKP having the longest pulse width, and the signal PCX<0> corresponds to the internal clock signal CKP having the shortest pulse width. The timing of the leading edge (or rising edge) of internal clock signal CKP is based on the sharper or shallower slope of signal PRE_CKP, which is controlled by transistors Te0, Te1, Te2, Te3 in FIG. 19, or transistors Tf0, Tf1, Tf2, Tf3 in FIG. 20. For example, the signal PCX<3> corresponds to the sharpest slope of signal PRE_CKP.

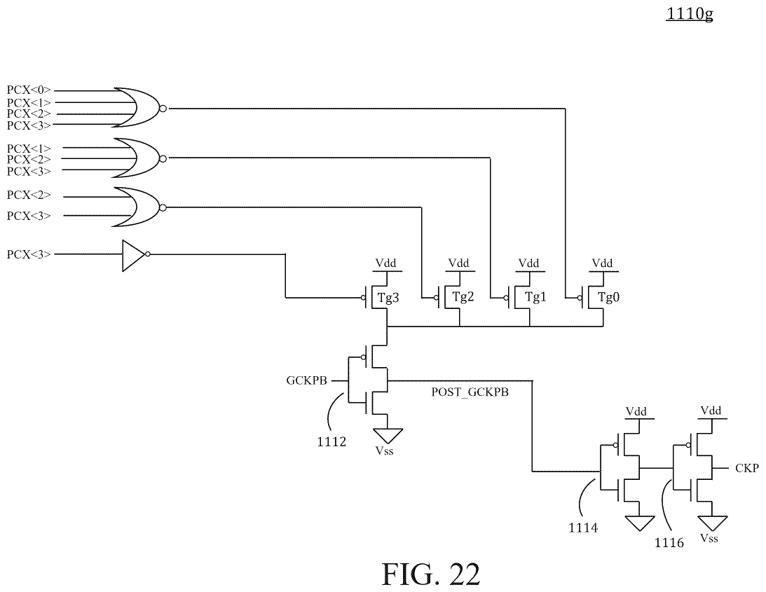

FIG. 22 is a schematic diagram of a variable internal clock signal pulse width generator 1110g according to an embodiment.

In FIG. 22, the variable internal clock signal pulse width generator 1110g receives row address-derived signals PCX<0:3> and the internal signal GCKPB, and outputs the internal clock signal CKP having a pulse width that varies based on the row address-derived signals PCX<0:3>.

In detail, in the variable internal clock signal pulse width generator 1110g, inverters 1112, 1114, and 1116 are coupled in stages, with the output of inverter 1112 coupled to the input of inverter 1114, and the output of inverter 1114 coupled to the input of inverter 1116. The internal signal GCKPB is input to inverter 1112, and the internal clock signal CKP is output from inverter 1116.

In FIG. 22, a signal POST_GCKPB, which is output from the inverter 1112 to the inverter 1114, is varied based on the row address-derived signals PCX<0:3> using four transistors Tg0, Tg1, Tg2, Tg3 that control a connection between the first supply voltage Vdd and a terminal of the inverter 1112. Gates of the transistors Tg0, Tg1, Tg2, Tg3 are controlled using the row address-derived signals PCX<0:3> in a manner similar to that described above in connection with FIG. 12, such that the signal PCX<3> corresponds to the internal clock signal CKP having the longest pulse width, and the signal PCX<0> corresponds to the internal clock signal CKP having the shortest pulse width.

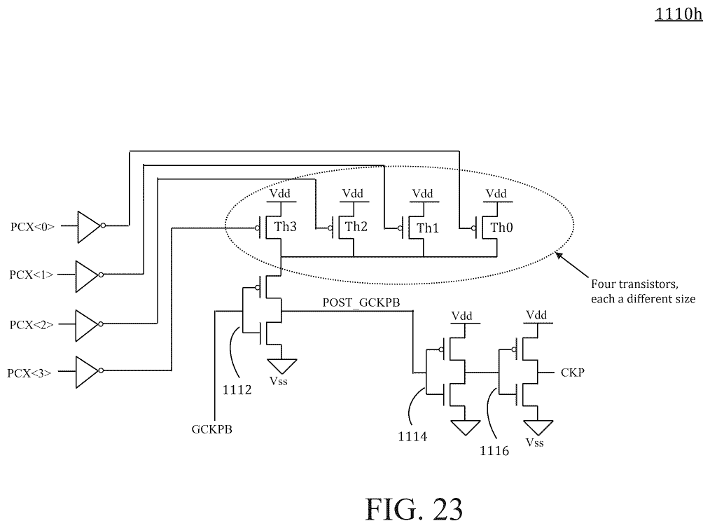

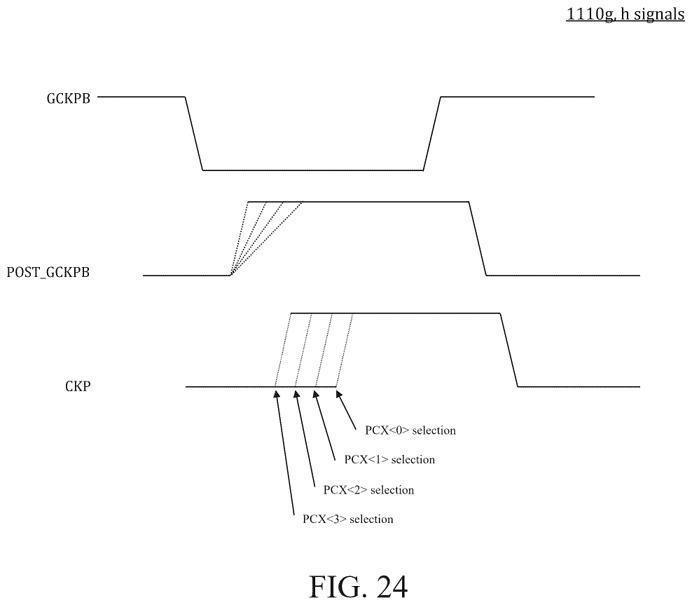

FIG. 23 is a schematic diagram of a variable internal clock signal pulse width generator 1110h according to an embodiment.

In FIG. 23, the variable internal clock signal pulse width generator 1110h receives row address-derived signals PCX<0:3> and the internal signal GCKPB, and outputs the internal clock signal CKP having a pulse width that varies based on the row address-derived signals PCX<0:3>. Also in FIG. 23, in the same manner as in FIG. 22, four transistors Th0, Th1, Th2, Th3 control a connection between the first supply voltage Vdd and a terminal of the inverter 1112.

In FIG. 23, NOR gates and corresponding inverters are not included. Instead, each of signals PCX<0:3> is provided to a corresponding one of transistors Th0, Th1, Th2, Th3. The transistors Th0, Th1, Th2, Th3 are each a different size with progressively larger sizes. That is, transistor Th0 is the smallest and transistor Th3 is the largest.

FIG. 24 is a graph of signals GCKPB, POST_GCKPB, and CKP corresponding to the variable internal clock signal pulse width generators 1110g and 1110h of FIGS. 22 and 23.

In FIG. 24, the signal PCX<3> corresponds to the internal clock signal CKP having the longest pulse width, and the signal PCX<0> corresponds to the internal clock signal CKP having the shortest pulse width. The timing of the leading edge (or rising edge) of internal clock signal CKP is based on the sharper or shallower slope of signal POST_GCKPB, which is controlled by transistors Tg0, Tg1, Tg2, Tg3 in FIG. 22, or transistors Th0, Th1, Th2, Th3 in FIG. 23. For example, the signal PCX<3> corresponds to the sharpest slope of signal POST_GCKPB.

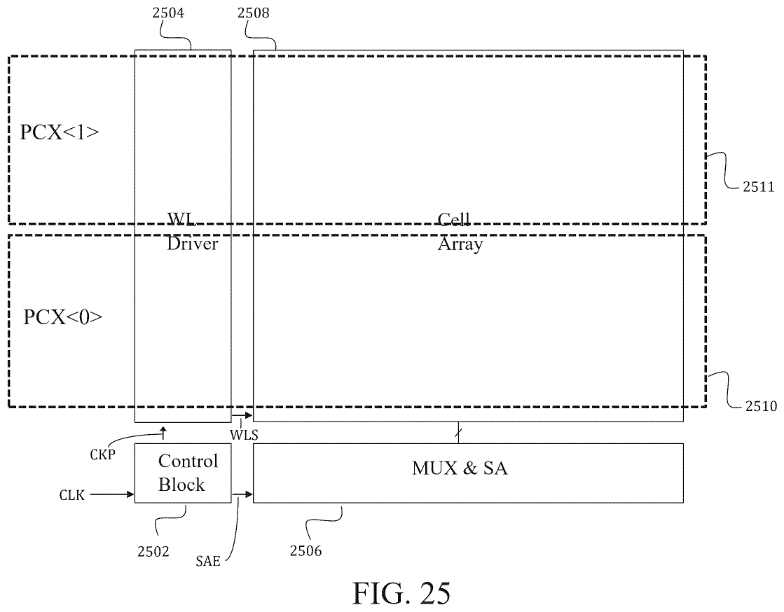

FIG. 25 is a block diagram of a memory device according to an embodiment.

In FIG. 25, an organizational scheme is described for a memory device having two word line driver groups 2510-2511, each addressed by one bit from PCX<0> to PCX<1>, by way of example. Each group of word lines of word line driver groups 2510-2511 associated with each address bit PCX<0> to PCX<1> is increasingly far from MUX & sense amplifier (SA) components 2506 in ascending order of PCX. That is, word lines of word line driver group 2510, addressed by bit PCX<0>, are closer to MUX & SA components 2506 than word lines of word line driver group 2511 addressed by PCX<1>. Accordingly, each of the individual word lines in word line driver group 2511, addressed by PCX<1>, takes a longer amount of time for the read margin to develop at MUX & SA components 2506 than the word lines of word line driver group 2510, addressed by PCX<0>.

In an embodiment, control block 2502 receives external input signals (e.g., CLK or ADDR) and generates the internal clock signals (e.g., internal clock signal CS or CKP) and the sense amplifier enable signal SAE. In this example, the control block 2502 generates an internal clock signal CKP having one of two different pulse widths (each of the two different pulse widths associated with each of the two PCX addressable groups 2510-2511). The internal clock signal CKP is output from the control block 2502 to the word line driver 2504. The word line driver 2504 generates word line signals WLS having different pulse widths WPW according to the different pulse widths of the internal clock signal CKP, and thus according to the different word lines WL being addressed. The word line driver 2504 outputs the word line signals WLS to memory cell array 2508. The control block 2502 is configured to assert a sense amplifier enable signal SAE (e.g., by asserting sense amplifier enable signal SAE on the trailing edge (or falling edge) of the WL signal) associated with each of the two groups 2510-2511. The sense amplifier enable signal SAE is output from the control block 2502 to the MUX & SA components 2506. The MUX & SA components 2506 read data from the memory cell array 2508.

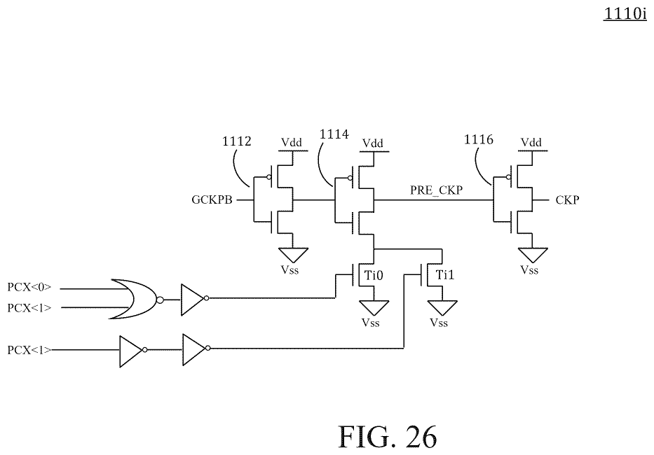

FIG. 26 is a schematic diagram of a variable internal clock signal pulse width generator 1110i according to an embodiment.

In FIG. 26, the variable internal clock signal pulse width generator 1110i receives row address-derived signals PCX<0:1> and the internal signal GCKPB, and outputs the internal clock signal CKP having a pulse width that varies based on the row address-derived signals PCX<0:1>.

In detail, in the variable internal clock signal pulse width generator 1110i, inverters 1112, 1114, and 1116 are coupled in stages, with the output of inverter 1112 coupled to the input of inverter 1114, and the output of inverter 1114 coupled to the input of inverter 1116. The internal signal GCKPB is input to inverter 1112, and the internal clock signal CKP is output from inverter 1116.

In FIG. 26, a signal PRE_CKP, which is output from the inverter 1114 to the inverter 1116, is varied based on the row address-derived signals PCX<0:1> using two transistors Ti0, Ti1 that control a connection between a terminal of the inverter 1114 and the second supply voltage Vss. Gates of the transistors Ti0, Ti1 are controlled using the row address-derived signals PCX<0:1> in a manner similar to that described above in connection with FIG. 12, such that the signal PCX<1> corresponds to the internal clock signal CKP having the longest pulse width, and the signal PCX<0> corresponds to the internal clock signal CKP having the shortest pulse width.

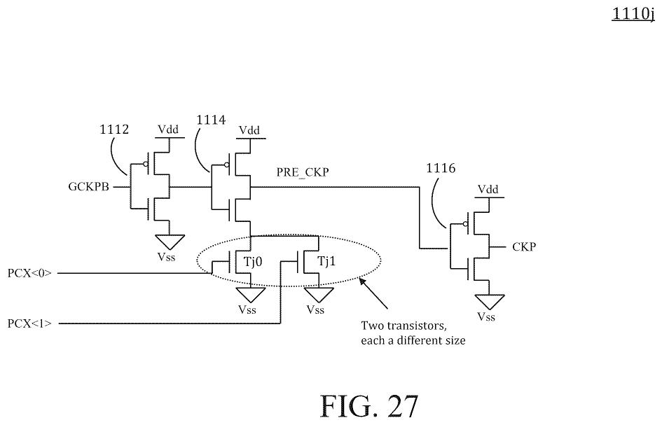

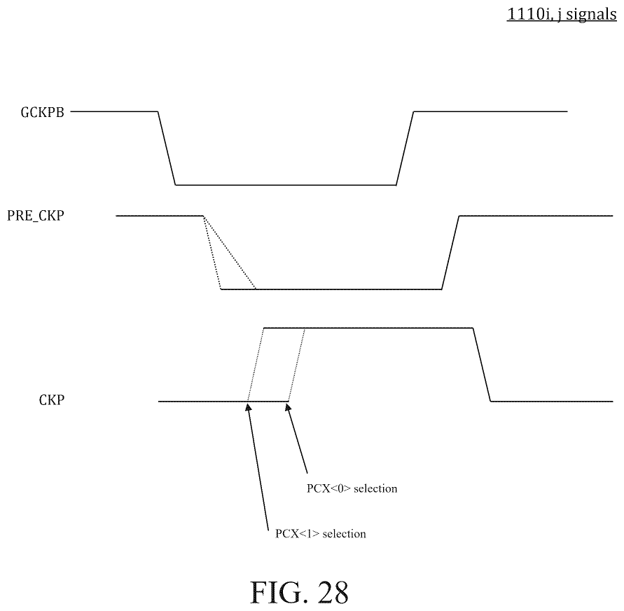

FIG. 27 is a schematic diagram of a variable internal clock signal pulse width generator 1110j according to an embodiment.

In FIG. 27, the variable internal clock signal pulse width generator 1110j receives row address-derived signals PCX<0:1> and the internal signal GCKPB, and outputs the internal clock signal CKP having a pulse width that varies based on the row address-derived signals PCX<0:1>. Also in FIG. 27, in the same manner as in FIG. 26, two transistors Tj0, Tj1 control a connection between a terminal of the inverter 1114 and the second supply voltage Vss.

In FIG. 27, NOR gates and corresponding inverters are not included. Instead, each of signals PCX<0:1> is provided to a corresponding one of transistors Tj0, Tj1. The transistors Tj0, Tj1 are each a different size with progressively larger sizes. That is, transistor Tj0 is the smallest and transistor Tj1 is the largest.

FIG. 28 is a graph of signals GCKPB, PRE_CKP, and CKP corresponding to the variable internal clock signal pulse width generators 1110i and 1110j of FIGS. 26 and 27.

In FIG. 28, the signal PCX<1> corresponds to the internal clock signal CKP having the longest pulse width, and the signal PCX<0> corresponds to the internal clock signal CKP having the shortest pulse width. The timing of the leading edge (or rising edge) of internal clock signal CKP is based on the sharper or shallower slope of signal PRE_CKP, which is controlled by transistors Ti0, Ti1 in FIG. 26, or transistors Tj0, Tj1 in FIG. 27. For example, the signal PCX<1> corresponds to the sharpest slope of signal PRE_CKP.

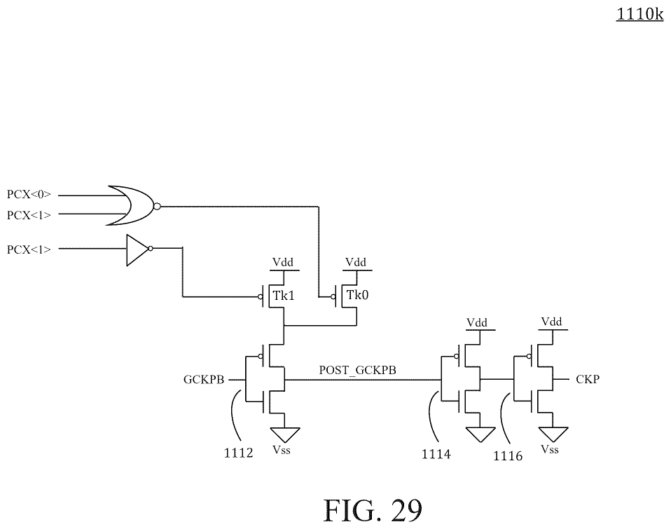

FIG. 29 is a schematic diagram of a variable internal clock signal pulse width generator 1110k according to an embodiment.

In FIG. 29, the variable internal clock signal pulse width generator 1110k receives row address-derived signals PCX<0:1> and the internal signal GCKPB, and outputs the internal clock signal CKP having a pulse width that varies based on the row address-derived signals PCX<0:1>.

In detail, in the variable internal clock signal pulse width generator 1110k, inverters 1112, 1114, and 1116 are coupled in stages, with the output of inverter 1112 coupled to the input of inverter 1114, and the output of inverter 1114 coupled to the input of inverter 1116. The internal signal GCKPB is input to inverter 1112, and the internal clock signal CKP is output from inverter 1116.

In FIG. 29, a signal POST_GCKPB, which is output from the inverter 1112 to the inverter 1114, is varied based on the row address-derived signals PCX<0:1> using two transistors Tk0, Tk1 that control a connection between the first supply voltage Vdd and a terminal of the inverter 1112. Gates of the transistors Tk0, Tk1 are controlled using the row address-derived signals PCX<0:1> in a manner similar to that described above in connection with FIG. 12, such that the signal PCX<1> corresponds to the internal clock signal CKP having the longest pulse width, and the signal PCX<0> corresponds to the internal clock signal CKP having the shortest pulse width.

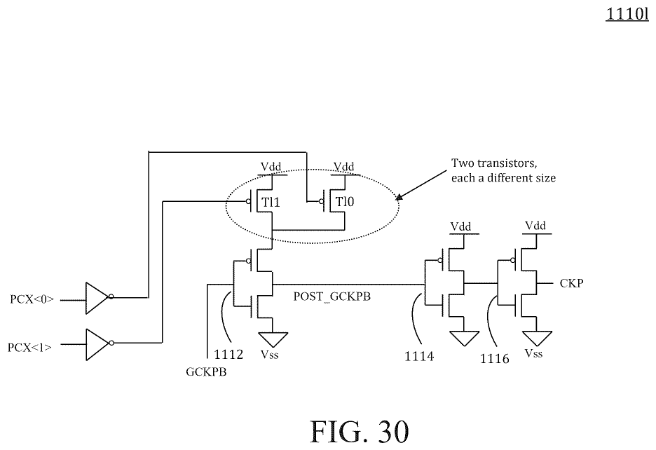

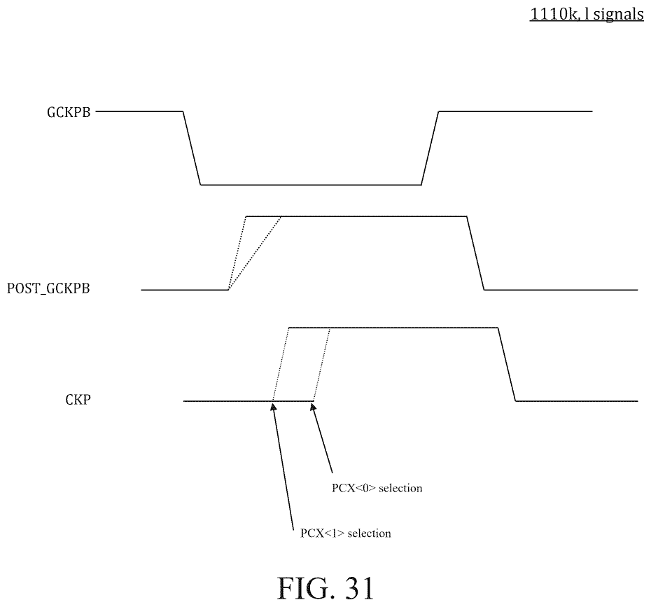

FIG. 30 is a schematic diagram of a variable internal clock signal pulse width generator 11101 according to an embodiment.

In FIG. 30, the variable internal clock signal pulse width generator 11101 receives row address-derived signals PCX<0:1> and the internal signal GCKPB, and outputs the internal clock signal CKP having a pulse width that varies based on the row address-derived signals PCX<0:1>. Also in FIG. 30, in the same manner as in FIG. 29, two transistors Tl0, Tl1 control a connection between the first supply voltage Vdd and a terminal of the inverter 1112.

In FIG. 30, NOR gates and corresponding inverters are not included. Instead, each of signals PCX<0:1> is provided to a corresponding one of transistors Tl0, Tl1. The transistors Tl0, Tl1 are each a different size with progressively larger sizes. That is, transistor Tl0 is the smallest and transistor Tl1 is the largest.

FIG. 31 is a graph of signals GCKPB, POST_GCKPB, and CKP corresponding to the variable internal clock signal pulse width generators 1110k and 1110k of FIGS. 29 and 30.

In FIG. 31, the signal PCX<1> corresponds to the internal clock signal CKP having the longest pulse width, and the signal PCX<0> corresponds to the internal clock signal CKP having the shortest pulse width. The timing of the leading edge (or rising edge) of internal clock signal CKP is based on the sharper or shallower slope of signal POST_GCKPB, which is controlled by transistors Tk0, Tk1 in FIG. 29, or transistors Tl0, Tl1 in FIG. 30. For example, the signal PCX<1> corresponds to the sharpest slope of signal POST_GCKPB.

In some embodiments described herein, a leading edge of a signal (or signal pulse) is referred to as a rising edge. In other embodiments, the leading edge of a signal is a falling edge. Likewise, in some embodiments described herein, a trailing edge of a signal (or signal pulse) is referred to as a falling edge. In other embodiments, the trailing edge of a signal is a rising edge.

According to some embodiments, a word line driving a memory cell is driven with a word line signal having a pulse width or period that is controlled or tailored based on the memory cell row address to develop a bit line voltage or read margin over a longer or shorter period of time. By driving the word line for the memory cell with a pulse having a relatively narrow pulse width for a word line relatively near to a sense amplifier, power is saved relative to using a fixed, longer pulse width for all word lines regardless of distance from the sense amplifier.

In an embodiment, a memory device includes a memory cell array including a first memory cell coupled to a first word line and a second memory cell coupled to a second word line; and a word line driver coupled to the memory cell array and configured to drive the first and second word lines with a word line signal having a pulse. A leading edge of the word line signal pulse is delayed for the word line signal applied to the first word line relative to the word line signal applied to the second word line.

In an embodiment, a memory device is configured to perform a read operation of a memory cell in which a pulse of a word line signal used to read the memory cell has a leading edge the timing of which is based on a row address of the memory cell.

In an embodiment, a method of operating a memory includes generating a first word line signal having a first word line signal pulse having a first word line signal pulse width, and applying the first word line signal to a first memory cell of a memory cell array; and generating a second word line signal having a second word line signal pulse having a second word line signal pulse width, and applying the second word line signal to a second memory cell of the memory cell array, the generating of the first word line signal including delaying a leading edge of the first word line signal pulse relative to a leading edge of the second word line signal pulse.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A memory device, comprising:
a memory cell array including a first memory cell coupled to a first word line and a second memory cell coupled to a second word line; and
a word line driver coupled to the memory cell array and configured to drive the first and second word lines with a word line signal having a pulse, wherein a leading edge of the word line signal pulse is delayed for the word line signal applied to the first word line relative to the word line signal applied to the second word line.

2. The memory device of claim 1, wherein the word line signal pulse has a width, and the word line signal pulse width is shorter for the word line signal applied to the first word line relative to the word line signal applied to the second word line.

3. The memory device of claim 1, further comprising a sense amplifier array configured to read data from the first and second memory cells, wherein:
a distance from the first word line to the sense amplifier array is a first distance,
a distance from the second word line to the sense amplifier array is a second distance, and
the first distance is less than the second distance.

4. The memory device of claim 1, further comprising:
a first sense amplifier and a first bit line that couples the first sense amplifier to the first memory cell; and
a second sense amplifier and a second bit line that couples the second sense amplifier to the second memory cell, wherein:
a length of the first bit line from the first sense amplifier to the first memory cell is a first distance,
a length of the second bit line from the second sense amplifier to the second memory cell is a second distance, and
the first distance is less than the second distance.

5. The memory device of claim 1, further comprising a clock generator configured to generate an internal clock signal with a varying pulse width, the internal clock signal pulse width being varied by varying timing of a leading edge of the internal clock signal based on a row address.

6. The memory device of claim 1, wherein the word line signal pulse for the word line signal applied to the first word line is shorter than the word line signal pulse for the word line signal applied to the second word line.

7. The memory device of claim 1, wherein a first read margin of the first memory cell is substantially the same as a second read margin of the second memory cell.

8. A memory device comprising a first memory cell and configured to perform a read operation of the first memory cell in which a pulse of a word line signal used to read the first memory cell has a leading edge the timing of which is based on a row address of the first memory cell.

9. The memory device of claim 8, further comprising:
a second memory cell; and
a sense amplifier array configured to read data from the first and second memory cells,
wherein:
the first memory cell is coupled to a first word line,
the second memory cell is coupled to a second word line,
a distance from the first word line to the sense amplifier array is a first distance,
a distance from the second word line to the sense amplifier array is a second distance that is greater than the first distance,
the pulse of the word line signal has a width, and
the width is greater for the word line signal applied to the second word line relative to the word line signal applied to the first word line.

10. The memory device of claim 9, wherein the leading edge of the pulse of the word line signal is not delayed for the word line signal applied to the second word line.

11. The memory device of claim 8, further comprising a clock generator configured to generate an internal clock signal, the clock generator being configured to receive address signals representing row addresses of the first and second memory cells, and to generate the internal clock signal with a pulse having a leading edge that is delayed for a row address corresponding to the first memory cell relative to a row address corresponding to the second memory cell.

12. The memory device of claim 11, wherein:
the clock generator receives an external clock signal having a pulse, and
the leading edge of the internal clock signal pulse is delayed, relative to a leading edge of the external clock signal pulse, for the row address corresponding to the first memory cell relative to the row address corresponding to the second memory cell.

13. The memory device of claim 8, further comprising:
a memory cell array including the first memory cell and a second memory cell; and
a word line driver coupled to the memory cell array,
wherein:
the first memory cell is coupled to a first word line,
the second memory cell is coupled to a second word line,
the word line driver is configured to drive the first and second word lines with the word line signal, and
a leading edge of a word line signal pulse is delayed for the word line signal applied to the first word line relative to the word line signal applied to the second word line.

14. The memory device of claim 13, wherein a first read margin of the first memory cell is substantially the same as a second read margin of the second memory cell.

15. A method of operating a memory, the method comprising:
generating a first word line signal having a first word line signal pulse having a first word line signal pulse width, and applying the first word line signal to a first memory cell of a memory cell array; and
generating a second word line signal having a second word line signal pulse having a second word line signal pulse width, and applying the second word line signal to a second memory cell of the memory cell array,
the generating of the first word line signal including delaying a leading edge of the first word line signal pulse relative to a leading edge of the second word line signal pulse.

16. The method of claim 15, wherein the first word line signal pulse width is generated to be shorter than the second word line signal pulse width.

17. The method of claim 15, further comprising reading data from the first and second memory cells using a sense amplifier array, wherein:
a distance from the first word line to the sense amplifier array is a first distance,
a distance from the second word line to the sense amplifier array is a second distance, and
the first distance is less than the second distance,
the reading the data from the first and second memory cells including ending a read operation of the first memory cell after a first elapsed time and ending a read operation of the second memory cell after a second elapsed time, the first elapsed time being shorter than the second elapsed time.

18. The method of claim 17, further comprising:
driving the sense amplifier array with a first sense amplifier enable signal having a first sense amplifier enable signal pulse to read the first memory cell; and
driving the sense amplifier array with a second sense amplifier enable signal having a second sense amplifier enable signal pulse to read the second memory cell, wherein:
the first elapsed time is a time from the leading edge of the first word line signal pulse to a leading edge of the first sense amplifier enable signal pulse, and
the second elapsed time is a time from the leading edge of the second word line signal pulse to a leading edge of the second sense amplifier enable signal pulse.

19. The method of claim 15, wherein generating the first and second word line signals includes controlling the first word line signal pulse width to be shorter than the second word line signal pulse width.

20. The method of claim 15, further comprising generating an internal clock signal having an internal clock signal pulse, the generating the internal clock signal including changing a timing of a leading edge of the internal clock signal pulse based on row addresses of the first and second memory cells,
wherein the changing timing of the leading edge of the internal clock signal pulse includes delaying the leading edge of the internal clock signal pulse for a row address corresponding to the first memory cell relative to a row address corresponding to the second memory cell.
